(19) United States
(12) Patent Application Publication
(10) Pub. No.: US 2023/0258739 A1
(43) Pub. Date: Aug. 17, 2023

(54) WIRE INSPECTION SYSTEM, WIRE INSPECTION METHOD, AND ELECTRIC WIRE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Fujio SONODA, Mie (JP); Xiaoguang ZHENG, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/913,584

(22) PCT Filed: Mar. 16, 2021
(86) PCT No.: PCT/JP2021/010480

§ 371 Date: Sep. 22, 2022

(30) Foreign Application Priority Data
Mar. 31, 2020 (JP) 2020-063441

(51) Int. Cl. G01R 31/58; G01R 31/54; G01R 31/52; H01B 7/32; H01B 7/02

(52) U.S. Cl. CPC G01R 31/58; G01R 31/54; G01R 31/52; H01B 7/32; H01B 7/02

(57) ABSTRACT

A wire inspection system has a memory unit which stores response signals obtained through wire inspection at a first time point for a plurality of electric wires constituting a wire group identifying individual electric wires, an inspection unit which performs the wire inspection on a subject electric wire selected from the wire group at a second time point later than the first time point, and an analysis unit which compares, for the subject electric wire, the response signal at the first time point retrieved from the memory unit, with the response signal obtained by the inspection unit at the second time point, and, if a difference exists between the two response signals, judges that damage exists on the subject electric wire.

### TECHNICAL FIELD

The present disclosure relates to a wire inspection system, a wire inspection method, and an electric wire.

### BACKGROUND ART

An electric wire is equipped or laid in various electrical and electronic equipment, transportation equipment, buildings, and public facilities; however, with long-term use of an electric wire, damage may occur to the electric wire, such as breakage, a short circuit, and external damage. For example, due to contact or friction between an electric wire and an object around the wire, damage may occur to an insulation coating arranged around an outer circumference of the electric wire. It is desirable to detect an occurrence of damage as early and sensitively as possible in order to avoid serious effects on a performance of the electric wire caused by the damage. Methods for detecting damage in an electric wire are disclosed in Patent Literatures 1 to 24, etc.

As a method for detecting damage of an electric wire, Patent Literature 11 discloses, for example, a cable diagnostic device including a setting means for setting a propagation speed of a pulse electrical signal for each of a plurality of sections in a cable path to be diagnosed, and an estimating means for estimating a defective point in the cable path based on a measurement result of reflection characteristics of the pulse electrical signal transmitted in the cable path and the propagation speed set for each section. Here, the propagation speed of each section is set by reading and setting data such as the number of cable paths using CAD, and a table indicating the relationship between the number of cables and the propagation speed is prepared in advance through experiments, and the propagation speed corresponding to the number of cables in each section of the cable path is automatically set.

### CITATION LIST

### Patent Literature

### [Patent Literature 1]: JP Sho63-157067 A

### [Patent Literature 2]: JP Hei4-326072 A

### [Patent Literature 3]: JP Hei6-194401 A

### [Patent Literature 4]: JP Hei7-262837 A

### [Patent Literature 5]: JP Hei7-282644 A

### [Patent Literature 6]: JP Hei8-184626 A

### [Patent Literature 7]: JP Hei11-332086 A

### [Patent Literature 8]: JP 2001-14177 A

### [Patent Literature 9]: JP 2006-518030 A

### [Patent Literature 10]: JP 2007-305478 A

### [Patent Literature 11]: JP 2007-333468 A

### [Patent Literature 12]: JP 2001-141770A

### [Patent Literature 13]: JP 2010-21049 A

### [Patent Literature 14]: JP 2011-217340 A

### [Patent Literature 15]: JP 2017-142961 A

### [Patent Literature 16]: JP 2019-128215 A

### [Patent Literature 17]: JP 2019-190875 A

### [Patent Literature 18]: JP 2020-15176 A

[Patent Literature 19]: U.S. Pat. No. 4,988,949 B2
[Patent Literature 20]: U.S. Pat. No. 6,265,880 B2

### [Patent Literature 21]: US 2003/206111 A

### [Patent Literature 22]: US 2007/021941 A

### [Patent Literature 23]:US 2010/253364 A

### [Patent Literature 24]: US 2011/309845 A

### SUMMARY OF APPLICATION

### Problems to be Solved by the Application

When determining presence or absence of damage and identifying a damaged position based on a response signal obtained through inputting an inspection signal to a component of an electric wire, it is necessary to compare the response signal with that in an absence of damage and perform a calculation with taking into account of characteristics of the electric wire. In this case, basic information obtained based on a preliminary test or a theory is used as the response signal to be compared and characteristics of the electric wire. As represented by automobiles, when many devices of the same type are manufactured and many electric wires of the same type equipped in the devices are also manufactured, as indicated in a table showing a relationship between the number of cables and propagation speed in the example of Patent Literature 11 described above, it is general that common basic information is applied to individual electric wires of the same type as basic information used to detect damage.

However, even for the electric wires of the same type, there are variations in characteristics within manufacturing tolerances for the individual electric wires, and an inspection using the common basic information may not be able to accurately detect damage. In particular, if the damage to the electric wire is that providing only a small change to the response signal, such as damage only on a surface of the electric wire, or if the electric wire as a structure such as a branched portion that affects the response signal, and if it is difficult to clearly recognize the change in the response signal due to a signal originating from the structure, it becomes difficult to detect damage using the basic information.

In addition to using comparisons and calculations based on the basic information, another possible method for detecting damage in an electric wire is to connect a measurement device to the electric wire at all times and keep monitoring the response signal. By way of continuously monitoring for a change in the response signal over time, any damage to the electric wire can be detected immediately by the change in the response signal. Since monitoring changes over time in the response signal of the individual electric wires, it is possible to sensitively detect damage occurring to the individual electric wires, even when there are variations in characteristics among the electric wires, without being affected by the variations. In this case, however, it is necessary to provide a measurement device to the individual electric wires, which lacks economic rationality.

In view of the above, the problem to be solved by the present disclosure is to provide a wire inspection system and a method that can detect damage in a plurality of the wires at low cost, even when there are variations in characteristics among the wires, and to provide an electric wire that is capable of being inspected using such a wire inspection system and a wire inspection method.

### Means of Solving the Problems

A wire inspection system for inspecting a damage state of an electric wire, wherein the electric wire including: a core wire including a conductor and an insulation coating, and a damage detection unit including at least one selected from a component of the core wire and a component other than the core wire which is arranged along the core wire, wherein the damage detection unit obtains a response signal which varies depending on the damage state of the electric wire when wire inspection is performed by inputting an electrical signal or an optical signal as an inspection signal, the wire inspection system including: a memory unit which stores the response signals obtained through the wire inspection at a first time point for a plurality of the electric wires constituting a wire group, identifying individual electric wires; an inspection unit which performs the wire inspection on a subject electric wire selected from the wire group at a second time point later than the first time point, and an analysis unit which compares, for the subject electric wire, the response signal at the first time point retrieved from the memory unit, with the response signal obtained by the inspection unit at the second time point, and, if a difference exists between the two response signals, judges that damage exists on the subject electric wire.

A wire inspection method using the wire inspection system, including: an initial data obtaining process in which the response signal is obtained at the first time point through the wire inspection performed on the electric wire included in the wire group; data storage process which stores the response signals obtained through the initial data obtaining process in the memory unit, identifying the individual electric wires; a measurement process which performs the wire inspection on the subject electric wire through the inspection unit the second time point, and the analysis process which compares, for the subject electric wire, the response signal obtained at the first time point retrieved from the memory unit, with the response signal obtained through the measurement process at the second time point, and if a difference exists between the two response signals, judges that damage exists on the subject electric wire.

A first wire of the present disclosure includes: a core wire including a conductor and an insulation coating covering an outer circumference of the conductor and exposed on a surface, and a conductive tape arranged around the outer circumference of the core wire, wherein the conductive tape is wound around the surface of the insulation coating in a spiral manner along the axial direction of the core wire, having gaps between turns in the spiral of the conductive tape that are not occupied by the conductive tape.

A second wire of the present disclosure includes: a core wire including a conductor and an insulation coating covering the outer circumference of the conductor and exposed on a surface; a laminated tape arranged on an outer circumference of the core wire, wherein the laminated tape includes a base material which is a tape-shaped insulator or a semiconductor, and conductive coating layers formed respectively on both sides of the base material.

### Advantageous Effects of Invention

The wire inspection system and the wire inspection method of the present disclosure enable detecting damage in a plurality of the electric wires at low cost, even when there are variations in characteristics among them. The electric wire of the present disclosure is capable of being inspected using such a wire inspection system and a wire inspection method.

### BRIEF DESCRIPTION OF DRAWINGS

FIG. 1 is a schematic view of a wire inspection system according to one embodiment of the present disclosure.

FIG. 2 is a flow chart illustrating a wire inspection method of one embodiment of the present disclosure.

FIG. 3 shows an example of a subject electric wire to be inspected.

FIGS. 4A to 4C show examples of response signals obtained through the wire inspection for the electric wire in FIG. 3. FIG. 4A shows a response signal in a case where no damage occurs to an individual electric wire 1, FIG. 4B shows a response signal in a case where damage occurs to the individual electric wire 1, FIG. 4C shows a subtraction between the cases where damage occurs to the individual electric wire 1 and no damage occurs to the individual electric wire 1. FIG. 4D shows a comparison of the response signals between the individual electric wires 1 and 2 on which no damage occurs, and FIG. 4E shows a subtraction between the response signals of the individual electric wires 1 and 2 on which no damage occurs.

FIG. 5 shows a schematic view of an electric wire wound with a conductive tape as an electric wire in accordance with a first embodiment of the present disclosure.

FIGS. 6A and 6B are cross-sectional views showing the electric wire wound with the conductive tape of FIG. 5 cut perpendicular to an axial direction, FIG. 6A showing a case where no damage occurs to the conductive tape and FIG. 6B showing a case where damage occurs to the conductive tape.

FIGS. 7A and 7B are cross-sectional views of an electric wire with a conductive layer formed on an entire circumference of a core wire, cut perpendicular to an axial direction; FIG. 7A showing a case where no damage occurs to the conductive layer and FIG. 7B showing a case where damage occurs to the conductive layer.

FIG. 8 is a schematic view of the electric wire wound with the conductive tape of FIG. 5 with bending, showing damage formed on the outside of the bent.

FIG. 9 shows a side view of the core wire with branched portions.

FIG. 10 is a schematic view describing an inspection for the electric wire wound with the conductive tape.

FIG. 11A is a schematic view showing a structure of an electric wire wound with a laminated tape as an electric wire of a second embodiment of the present disclosure. FIG. 11B is a cross-sectional view showing a stacking structure of the laminated tape.

FIG. 12 shows an example of a characteristic impedance measurement result in a case where simulated external damage is formed on a straight electric wire wound with the conductive tape.

FIG. 13 shows the characteristic impedance measurement result in a case where a position of external damage formed on the straight electric wire wound with the conductive tape is changed.

FIGS. 14A-14C show the characteristic impedance measurement results for the electric wire wound with the conductive tape with the branched portions, FIG. 14A showing the measurement result with no external damage, FIG. 14B showing the measurement result with external damage, and FIG. 14C displaying a subtraction signal.

FIGS. 15A to 15C show characteristic impedance measurement results for the straight electric wire wound with the laminated tape. FIG. 15A shows the measurement result with no external damage, FIG. 15B shows the measurement result with the laminated tape being broken, and FIG. 15C shows the subtraction signal.

FIGS. 16A to 16C show characteristic impedance measurement results for the straight electric wire wound with the laminated tape. FIG. 16A shows the measurement result with no external damage, FIG. 16B shows the measurement result with the two conductive layers of the laminated tape being shorted, and FIG. 16C shows the subtraction signal.

### DESCRIPTION OF EMBODIMENTS

[Explanation of Embodiments According to Present Disclosure]

First, embodiments of the present disclosure are explained.

A wire inspection system according to the present disclosure is for inspecting a damage state of an electric wire, wherein the electric wire including: a core wire including a conductor and an insulation coating; and a damage detection unit including at least one selected from a component of the core wire and a component other than the core wire which is arranged along the core wire, wherein the damage detection unit obtains a response signal which varies depending on the damage state of the electric wire when wire inspection is performed by inputting an electrical signal or an optical signal as an inspection signal, the wire inspection system including: a memory unit which stores the response signals obtained through the wire inspection at a first time point for a plurality of the electric wires constituting a wire group, identifying individual electric wires; an inspection unit which performs the wire inspection on a subject electric wire selected from the wire group at a second time point later than the first time point, and an analysis unit which compares, for the subject electric wire, the response signal at the first time point retrieved from the memory unit, with the response signal obtained by the inspection unit at the second time point, and, if a difference exists between the two response signals, judges that damage exists on the subject electric wire.

In the above-described wire inspection system, the memory unit stores the response signals obtained through the wire inspection at the first time point for a plurality of the electric wires constituting a wire group, identifying individual electric wires; the inspection unit performs the wire inspection on a subject electric wire at the second time point, and the analysis unit compares, for the subject electric wire, the response signal at the first time point retrieved from the memory unit, with the response signal obtained by the inspection unit at the second time point. Therefore, if damage occurs to the subject electric wire between the first and second time points, the damage can be detected by detecting the change between the response signals. Since the memory unit stores therein the response signal for individual electric wire at the first time point, and the response signal for the subject electric wire to which the inspection is actually performed at the second time point is retrieved from the memory unit, the detection of damage in the individual electric wire can be performed without being affected by variations, if any, in the response signals of the individual electric wire constituting the wire group, based on a comparison of the response signals at the first and second time points. By storing the response signals of the individual electric wires in the memory unit, there is no need to connect a measurement device to the individual electric wires at all times to keep monitoring the response signal, thus enabling a detection of damage based on a change between the response signals of the individual electric wires at low cost.

Here, the memory unit may be installed at a position apart from the inspection unit and the analysis unit. By installing the memory unit as an information management server at the position apart from the inspection unit and the analysis unit, the response signals at the first time point for a large number of the electric wires can be stored and managed centrally by identifying the individual electric wires. Further, even when inspection is individually performed on a large number of the electric wires using the inspection unit and the analysis unit arranged at various positions, the response signals at the first time point for the individual electric wires can be provided from the memory unit to the analysis unit at each position for use in damage detection.

It is preferable that the analysis unit finds the subtraction between the response signals at the first and second time points, and determines whether a difference exists between the two response signals based on the subtraction. By finding the subtraction between the two response signals, if damage occurs to the subject electric wire between the first and second time point and causes a change between the response signals, it is possible to sensitively detect the change between the response signals. This is because, by using the subtraction, even if the electric wire has elements including branched portions, for example, that give structures such as peaks or waves in the response signals, the contribution from these elements can be cancelled out and the contribution from damage can be emphasized in the response signal.

It is preferable that the damage detection unit includes two conductive members electrically insulated from each other, wherein, in the wire inspection, characteristic impedance between the two conductive members is measured as the response signal using an electrical signal including an alternate-current component as the inspection signal, by a time domain reflectometry or a frequency domain reflectometry, wherein the analysis unit correlates a domain where a difference exists between the response signals at the first and second time points with a position along an axial direction of the wire, and judges that damage exists at the position. By measuring the characteristic impedance between the two conductive members in the electric wire, the change due to damage can be sensitively detected when damage occurs to the electric wire. By measuring the characteristic impedance by either one of the time domain reflectometry or the frequency domain reflectometry, a damaged position along the wire axis can be easily and accurately identified from information on an area where a change in characteristic impedance occurs on the response signal, through appropriate calculations. Since the measurement by using the reflectometry can be performed simply by connecting the measurement device to one end of the electric wire, the damage detection can be conveniently performed on the spot, even when the electric wire cannot be easily removed.

In this case, the inspection signal includes a superimposition of signal components existing over a continuous frequency range and having mutually independent intensities, and has exclusion frequencies occupying a part of the frequency range, at which the components have no intensities or discontinuously smaller intensities than the components at adjacent frequencies; wherein in the wire inspection, the characteristic impedance between the two conductive members is measured as the response signal by time domain reflectometry. In this case, the damage detection can be performed using an advantage of the time domain reflectometry, such as the ability to directly convert information on the time when a change in characteristic impedance is found into information on the position where damage occurs on the electric wire, as well as the advantage of using the inspection signals with different frequency components superimposed, such as the ability to measure the characteristic impedance with reduced effects from external noise. Especially, if the inspection signal includes, within the continuous frequency range, the frequency components having no intensities or discontinuously smaller intensities, it is possible to effectively reduce an influence of noise in the frequency components.

Further, in the inspection signal, it is preferable that the exclusion frequencies includes frequencies of electromagnetic waves originating from a generation source external to the subject electric wire in a state of propagating around the subject electric wire. In this case, by setting the exclusion frequencies so as to include the frequencies for use in communication among the other communication devices in the vicinity when setting a waveform of the inspection signal, it is possible to perform the characteristic impedance measurement using the inspection signal as well as the detection of damage based on the measurement result while reducing influence of noise associated with the communication among the device in the vicinity, when the subject electric wire is used in the environment where other communication devices or communication wires exist in the vicinity such as inside an automobile.

The wire group includes a plurality of the electric wires of the same type. For the electric wires of the same type, even if there is no significant differences in the response signals of the individual electric wires when the wire inspection is performed, variations exist within the manufacturing tolerances. Therefore, the response signals obtained for the individual electric wires at the first time point are stored in the memory unit, identifying the individual electric wires, so that the damage detection can be performed sensitively and with high accuracy based on the comparison of the response signals for a specific one of the individual electric wires to which the wire inspection is performed at the second time point.

It is preferable that the electric wires included in the wire group have branched portions in the middle of the wire. When the branched portions exist in the electric wire, large structural components originated from the branched portions are often generated in the inspection signal and the response signal, and the change between the response signals due to damage is easily buried. However, by retrieving the response signal obtained for the subject electric wire at the first time point and comparing it with the response signal obtained at the second time point, damage tends to be accurately detected even if there are contributions from the signal components originated from the branched portions and other parts of the electric wire.

It is preferable that the electric wire to be inspected includes a conductive tape wound around an outer circumference of the core wire in a spiral manner, having gaps between turns of the conductive tape that are not occupied by the conductive tape, wherein the damage detection unit is composed of the conductor of the core wire and the conductive tape, wherein, in the wire inspection, the characteristic impedance between the conductor and the conductive tape is measured as the response signal using the electrical signal including an alternate-current component as the inspection signal. In this case, if external damage occurs to the electric wire and damage is formed also on the conductive tape, the characteristic impedance between the conductive tape and the conductor including the core wire changes. Because the conductive tape is spirally wound around the electric wire leaving the gaps between the turns, the capacitance between the conductive tape and the conductor of the core wire changes significantly even if damage occurs only in an area along the circumferential direction of the electric wire. As a result, a significant change in the characteristic impedance between the conductive tape and the core wire can occur. Therefore, by measuring the characteristic impedance between the conductive tape and the conductor of the core wire, it is possible to sensitively detect that damage was formed on the electric wire.

In this case, it is preferable that the core wire has a single wire structure including only one insulated wire with the insulation coating on an outer circumference of the conductor. Unlike the case of a shielded cable or a paired cable, the core wire having the single wire structure does not have multiple conductive members inside the core wire that can measure the characteristic impedance and thus cannot be used to measure the characteristic impedance inside the core wire nor detect damage. However, even if the core wire has the single wire structure, it is possible to detect damage based on the characteristic impedance by winding the conductive tape around the circumference of the core wire. In this case, the conductor of the core wire itself is also used as the damage detection unit, and therefore, it is enough to have a simple structure of the conductive tape wound around the circumference as a dedicated member for the damage detection.

Alternatively, the subject electric wire to be inspected includes a laminated tape arranged around the outer circumference of the core wire, wherein the laminated tape includes: a base material which is a tape-shaped insulator or a semiconductor, and conductive coating layers formed on both sides of the base material, and the damage detection unit is composed of two coating layers in the laminated tape, wherein, in the wire inspection, the characteristic impedance between the conductor and the conductive tape is measured as the response signal using the electrical signal including an alternate-current component as the inspection signal. In this case, if external damage occurs to the electric wire and damage such as breakage in the coating layer or a short circuit between the coating layers is formed on the laminated tape, the characteristic impedance between the two coating layers changes. Therefore, by measuring the change in the characteristic impedance between the two coating layers, it is possible to sensitively detect that damage was formed on the electric wire. Since measurement is performed between the two coating layers provided on the laminated tape, a damage detection function can be provided to various forms of the electric wires simply by winding the laminated tape around them.

In this case, the core wire is in the form of a wire harness with a plurality of the electric wires made into a bundle, and the laminated tape is wound in a spiral manner around the outer circumference of the wire harness as a whole. In this case, the laminated tape can be used to sensitively detect damage formed on the outer circumference of the wire harness as a whole, regardless of the configuration of the wire harness, such as shape and thickness.

The base material changes its electrical properties depending on an external environment. In this case, changes in the electrical properties of the base material due to changes in the external environment, such as temperature and humidity, may also cause changes in characteristic impedance between the two coating layers. In this case, not only physical damage but also the effects of environmental changes such as temperature and humidity on the wire can be detected.

The wire inspection method using the wire inspection system, includes: an initial data obtaining process in which the response signal is obtained at the first time point through the wire inspection performed on the electric wire included in the wire group; a data storage process which stores the response signals obtained through the initial data obtaining process in the memory unit, identifying the individual electric wires; a measurement process which performs the wire inspection on the subject electric wire through the inspection unit at the second time point, and the analysis process which compares, for the subject electric wire, the response signal obtained at the first time point retrieved from the memory unit, with the response signal obtained through the measurement process at the second time point, and if a difference exists between the two response signals, judges that damage exists on the subject electric wire.

In the above-described wire inspection method, in the initial data obtaining process and the data storage process, the individual electric wires constituting the wire group are identified and the response signals obtained through the wire inspection are stored in the memory unit. Then, in an inspection process, the wire inspection is performed on the specific wire, and in the analysis process, the response signal corresponding to that of the subject electric wire is retrieved from the memory unit and the response signals at the first and second time points are compared. Therefore, if damage occurs to the subject electric wire between the first and second time points, the damage can be found by detecting the change between the response signals. Even if there are variations in the response signals of the individual electric wires constituting the wire group, the detection of damage in the individual electric wires can be performed based on the comparison of the response signals at the first and second time points, without being affected by such variations, and the detection of damage can be performed sensitively and with high accuracy. Since there is no need to connect the measurement device to the individual electric wires at all times to keep monitoring the response signals, this inspection method enables a detection of damage based on the change in the response signals of the individual electric wires at low cost.

A first electric wire of the present disclosure includes: a core wire including a conductor and an insulation coating covering the outer circumference of the conductor and exposed on the surface, and a conductive tape arranged around the outer circumference of the core wire, wherein the conductive tape is wound around a surface of the insulation coating in a spiral manner along the axial direction of the core wire, having gaps between turns in the spiral of the conductive tape that are not occupied by the conductive tape.

The first electric wire has the conductive tape wound around the outer circumference the core wire, and if damage occurs to the conductive tape, the characteristic impedance between the conductive tape and the conductor including the core wire changes. As a component for detecting damage, the conductive tape is wound around the core wire with a conductive substance in a spiral manner, leaving the gaps between the turns, rather than continuously covering the entire circumference of the electric wire, so that even if damage occurs in only an area along the circumference of the electric wire, the capacitance between the conductive tape and the conductor including the core wire changes significantly. As a result, a significant change in the characteristic impedance between the conductive tape and the conductor including the core wire can occur. Therefore, by measuring the characteristic impedance between the conductive tape and the conductor including the core wire, it is possible to sensitively detect that damage is formed on the electric wire.

A second electric wire of the present disclosure includes: a core wire including a conductor and an insulation coating covering an outer circumference of the conductor and exposed on the surface; a laminated tape arranged around an outer circumference of the core wire, wherein the laminated tape includes a base material which is a tape-shaped insulator or a semiconductor, and conductive coating layers formed respectively on both sides of the base material.

In the second electric wire, when damage is formed on the laminated tape, the characteristic impedance between the two coating layers changes. Therefore, by measuring the change in characteristic impedance between the two coating layers, it is possible to sensitively detect that damage was formed on the electric wire. Since the measurement is completed between the two coating layers of the laminated tape, rather than using the conductor or other components of the core wire for damage detection, a function of the damage detection can be provided to the electric wires in various forms, such as the wire harness with a plurality of the electric wires made into a bundle, simply by winding the laminated tape. If a material whose electrical properties change with changes in the external environment is used as the base material, not only physical damage but also the effects of environmental changes such as temperature and humidity on the electric wire can be detected as changes in characteristic impedance between the two coating layers.

### Details of Embodiments According to Present Disclosure

Concrete examples of a wire inspection system, a wire inspection method, and an electric wire according to the present disclosure are explained hereunder in reference to the drawings. The wire inspection system according to an embodiment of the present disclosure is a system that can inspect damaged state of an electric wire, and the wire inspection method according to an embodiment of the present disclosure can be performed using the wire inspection system. An example of the electric wire to which the wire inspection system and the wire inspection method can be preferably applied is the electric wire of the embodiment of the present disclosure. In the specification, the words used to indicate a shape and an arrangement of the components of the electric wire, such as perpendicular, orthogonal, straight, or spiral, shall include not only geometrically strict concepts, but also errors within the range allowed in the wire.

### <Subject Electric Wire to be Inspected>

First, the electric wire to be inspected in the wire inspection system and the wire inspection method of an embodiment of the present disclosure are described. The electric wire to be inspected, similar to a normal wire, includes a core wire including a conductor and an insulation coating covering the outer circumference of the conductor, and is also provided with a damage detection unit. The damage detection unit obtains a response signal which varies depending on the damage state of the electric wire when wire inspection is performed by inputting an electrical signal or an optical signal as an inspection signal. In the wire inspection, the response signal obtained by the damage detection unit varies depending on the damage state of the electric wire, i.e., presence or absence of damage to the electric wire, and more preferably, the degree and a damaged position.

The damage detection unit includes at least one of components of the core wire and a component other than the core wire which is arranged along the core wire. Depending on which component is employed, the damage detection unit can be classified into the following three forms.

### (i) Damage Detection Unit Consisted Only of Component of Core Wire

In this form, although each component of the core wire plays its original roles as the electric wire such as supplying power, transmitting signals, or shielding noise, each component of the core wire is made to play a role as the damage detection unit in addition to their original roles. For example, a conductive member such as a conductor that includes the core wire functions as the damage detection unit. The number of the conductive member to function as the damage detection unit is not limited. For example, the wire inspection may be performed by passing an electrical signal from one end of the conductive member to the other end, or by evaluating the electrical characteristics between two mutually insulated conductive members. Specific examples for using two conductive members include a form of using a twisted pair wire (wire C), which is given as an example in a detailed description described later, in which the two conductors in the core wire are used as the damage detection unit, and a form of using a coaxial shielded cables in which a central conductor and a shielded conductor are used as the damage detection unit.

(ii) Damage Detection Unit Consisted Only of Component Other than Core Wire

In this case, each component of the core wire is not used as the damage detection unit. Instead, a component specialized for damage detection is arranged outside the core wire and included in the electric wire together with the core wire. For example, a tape body or a linear body including the conductive member may be arranged around the outer circumference of the core wire for use as the damage detection unit. Again, in this case, the wire inspection may be performed by passing an electric signal from one end of the conductive member arranged outside the core wire to the other end, or by arranging the component including the two mutually insulated conductive members outside the core wire to evaluate the electrical characteristics between the two conductive members. As a specific example of a form in which the damage detection component including the two conductive members is arranged around the outer circumference the core wire, there is raised a form using an electric wire 3 wound with a laminated tape, which will be described later as a second electric wire of an embodiment of the present disclosure, that is, the laminated tape having two conductive coating layers is wound around the outer circumference of the core wire and the electrical characteristics between the two conductive coating layers are evaluated. When the form mentioned in (ii) is adopted, an optical signal can also be used as the inspection signal instead of an electrical signal. For example, an optical fiber can be run along the core wire, and the wire inspection can be performed by transmission of the optical signal in the optical fiber.

(iii) Damage Detection Unit Consisted Only of Component of Core Wire and Component Other than Core Wire

In this case, each component of the core wire and the component arranged outside the core wire work together to function as the damage detection unit. For example, the conductive member of the core wire, such as the conductor, and another conductive member arranged around the outer circumference of the core wire may constitute the damage detection unit. A specific example is a form of using an electric wire 1 wound with a conductive tape, which will be described later as a first electric wire of an embodiment of the present disclosure, i.e., the conductive tape is wound around the outer circumference of the core wire, and electrical characteristics between the conductive tape and the conductor of the core wire are evaluated.

In any of the forms (i) to (iii), the characteristics to be measured in the wire inspection should be selected according to the specific configuration of the damage detection unit, so that damage formed on the electric wire, such as breakage, a short circuit, or external damage, can be detected. When an electrical signal is used as an input signal, characteristic impedance, or other characteristics that have a correlation with the characteristic impedance, such as reflection coefficient, conductance, and capacitance can be given as examples as characteristics to be measured, i.e., characteristics to be measured as the response signal. These characteristics may be measured using a transmission method or a reflection method. In the following description, a case where measuring the characteristic impedance will be mainly described, but even if not noted, the characteristics that have a correlation with the characteristic impedance can be used for the wire inspection as an object to be measured instead of the characteristic impedance. When the optical signal is used as the input signal, various characteristics of transmission and reflection of the optical signal can also be measured as the response signal.

In the following descriptions of the wire inspection system and the wire inspection method, the twisted pair wire, which correspond to the form (i), is employed as an example of the electric wire to be inspected. In the twisted pair wire, two insulated wires are twisted together to form the core wire. Below, there will be described a form in which the electrical signal containing the alternate-current component is input as the inspection signal to the conductor including the two insulated wires, and the characteristic impedance between the two conductors is detected as the response signals using the reflection method. In the twisted pair wire, a short circuit or other damage between the two conductors causes a change in the characteristic impedance between the two conductors.

There is no particular limitation of an application and a position of use of the subject electric wire to be inspected using the inspection system and the inspection method of the embodiment of the present disclosure, and examples of the electric wire include an electric wire mounted inside various electrical and electronic equipment and transportation equipment such as automobiles and aircrafts, an electric wire laid in houses, buildings, and an electric wire constituting public facilities such as power transmission lines. However, the inspection system and the inspection method described below are highly effective in a form where many electric wires of the same type are used in a wide area, and it is preferable that they are equipped in mass-produced equipment such as electrical and electronic equipment and transportation equipment. Below is a description with an assumption that the electric wires are mounted in an automobile.

### <Wire Inspection System>

Next, a wire inspection system according to a first embodiment of the present disclosure will be described.

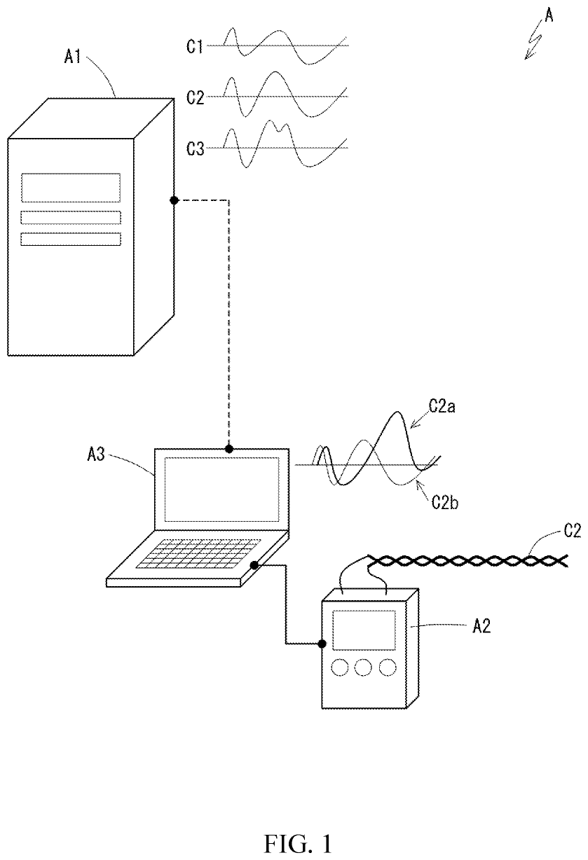

A schematic view of the wire inspection system A is shown in FIG. 1. The wire inspection system A has a memory unit A1, an inspection unit A2, and an analysis unit A3. The memory unit A1 is a device that can store data and made as an information management server. The memory unit A1 may be in the form of a cloud server. The inspection unit A2 is in the form of a measurement device that can perform the wire inspection on individual electric wires, i.e., input an inspection signal and obtain a response signal. The analysis unit A3 is a device that can perform wired or wireless communication with the memory unit A1 (indicated by a dashed line in the figure), retrieve data from the memory unit A1, and compare the retrieved data with data obtained in the inspection unit A2. Examples as the analysis unit A3 include a CPU provided integrally with the inspection unit A2, or a computer provided in the vicinity of the inspection unit A2 and capable of inputting data from the inspection unit A2 by wire or wireless means.

It is preferable that the memory unit A1 is installed at a position apart from the inspection unit A2 and the analysis unit A3. For example, the memory unit A1 can be installed as a server managed by a manufacturer of the electric wire or an automobile or on the cloud, and the inspection unit A2 and the analysis unit A3 can be installed under the supervision of an inspection service provider, such as a car dealer or a car inspection factory. A large number of the inspection unit A2 and the analysis unit A3 can be installed, and they can be installed in each of a large number of stores or factories located in a wide area. Further, each analysis unit A3 can communicate with a common memory unit A1 via the internet or other means.

The memory unit A1 can store the response signals obtained through the wire inspection for a large number of the electric wires for the individual electric wires. The memory unit A1 stores therein the response signals obtained for a large number of the electric wires at the first time point. Here, the first time point refers, for example, to an initial state of the electric wire before manufactured and put into use. In the initial state, the wire inspection, i.e., inputting of the inspection signal and obtaining the response signal, is performed by a manufacturer of the electric wire or a manufacturer of an automobile for the individual electric wires using the measurement device similar to the inspection unit A2, and the obtained response signal is stored in the memory unit A1. In this case, the response signals obtained for a wire group including a plurality of the electric wires is stored for the individual electric wires. In other words, each of the response signals for the individual electric wires included in the wire group is tied to the individual electric wires by an assignment of a serial number, and is individually stored. FIG. 1 shows the response signals of electric wires C1 to C3, individually stored (three waveforms shown to the right of the memory unit A1 in FIG. 1). In the example shown here, the response signal is assumed to be characteristic impedance measured for the individual electric wires in the form of a twisted pair wire.

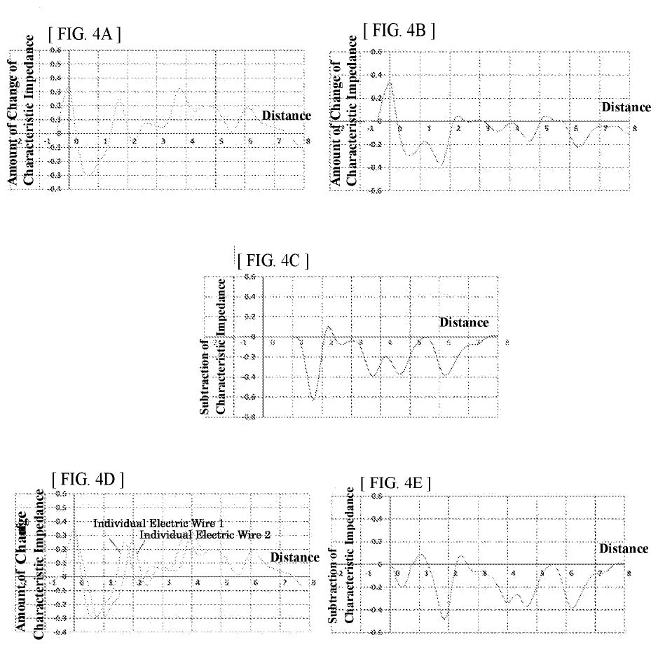

It is preferable that a wire group for which the response signals are stored in the memory unit A1 includes a plurality of the electric wires of the same type. The electric wires of the same type refer to electric wires manufactured according to the same design and having the same structure. For example, the wire group includes the electric wires that are equipped with a large number of vehicles as the electric wires that are routed to the same position of the same car model. A plurality of the electric wires of the same type may include variations in construction and/or characteristics within manufacturing tolerances. Due to the variations, differences may exist in the response signals of the individual electric wires, even for the same type (see FIG. 4D). In the memory unit A1, the response signals are stored for the individual electric wires, so that even if there are differences in the response signals due to the variations, the response signals for the individual electric wires are stored as they are, including the differences.

The inspection unit A2 performs the wire inspection for a specific wire selected from the wire group at a second time point later than the first time point. For example, the second time point is at the time of inspection performed as periodic car inspection after the automobile equipped with the electric wires is put into use. At this time, the measurement device that includes the inspection unit A2 is connected to the electric wire, and inputting the inspection signal as well as obtaining the response signal are performed. The illustrated example is under an assumption of a form in which the inspection unit A2 measures the characteristic impedance using time domain reflectometry as the wire inspection for the electric wire C2 in the form of the twisted pair wire.

The analysis unit A3 can read the response signal obtained by the inspection unit A2 from the memory unit A1. Further, the analysis unit A3 can communicate with the memory unit A1 and retrieve the response signal corresponding to a specific individual electric wire from a plurality of the response signals stored in the memory unit A1. When the inspection is performed, the analysis unit A3 retrieves the response signal in the initial state of the individual electric wire inspected by the inspection unit A2 from the memory unit A1. In a form shown in the figure, the analysis unit A3 retrieves the response signal of the electric wire C2 which is subject to inspection from the response signals in the initial state of the electric wires C1 to C3 stored in the memory unit A1.

Furthermore, the analysis unit A3 compares the response signal (C2a) obtained by the inspection unit A2 for the subject electric wire C2 at the time of inspection with the response signal (C2b) obtained in the initial state retrieved from the memory unit A1. Then, a determination is made whether or not a difference exists between the two response signals C2a and C2b. If a difference of more than a predetermined level exists, a judge is made that damage exists in the subject electric wire C2 that did not exist in the initial state of the wire. It is preferable that, when comparing the response signals, the analysis unit A3 finds the subtraction between the response signal C2a at the time of inspection and the response signal C2b in the initial state, and determines whether or not a difference exists between the response signals based on the subtraction. That is, it is preferable that the judge that damage exists is made when the subtraction indicates intensity in the positive or negative direction that exceeds a predetermined threshold value. Where possible, depending on the type of the electric wire or the wire inspection, it is more preferable if the analysis unit A3 can analyze a result of the comparison of the response signals in more detail and identify a type and/or a damaged position. A method of analysis using the subtraction and a method of specifying a damaged position will be explained later with specific examples.

### <Wire Inspection Method>

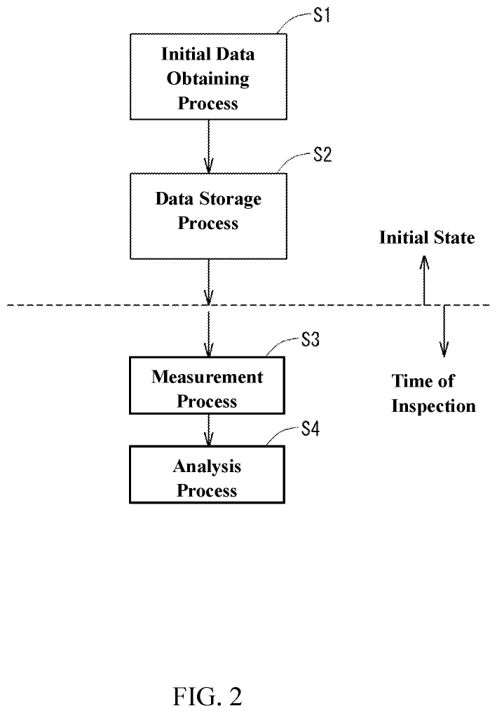

Next, a wire inspection method of one embodiment of the present disclosure using the wire inspection system A will be briefly described. FIG. 2 shows a flow diagram of the wire inspection method.

In the wire inspection method, an initial data obtaining process S1 and a data storage process S2 are performed at a first time point. At a second time point, a measurement process S3 and an analysis process S4 are performed. The first time point refers to an initial state in which a vehicle equipped with an electric wire is not put into use, and the initial data obtaining process S1 and the data storage process S2 are performed by a manufacturer of an electric wire or a manufacturer of automobile. On the other hand, the second time point refers to a time of the inspection after the electric wire is put into use, and the measurement process S3 and the analysis process S4 are performed by an inspection service provider, such as a car dealer or a car inspection factory.

In the initial data obtaining process S1, a wire inspection is performed using a measurement device similar to the inspection unit A2, that is, inputting an inspection signal to the electric wire and obtaining a response signal are performed. The wire inspection is performed on each of a plurality of the electric wires included in a wire group. In an example mentioned in FIG. 1, characteristic impedance between conductors is measured for each electric wire (the electric wires C1 to C3) in the form of a twisted pair wire.

Then, in the data storage process S2, the response signals (i.e., measurement results of the characteristic impedance) obtained in the initial data obtaining process S1 is stored in the memory unit A1 for the individual electric wires. In other words, the response signals are stored in the memory unit A1 with the response signals tied to the individual electric wires by assigning a serial number, respectively. It is preferable that the wire group for which the response signals are stored in the memory unit A1 includes a plurality of the electric wires of the same type.

Then, an automobile equipped with the electric wire is put into use, and the time for inspection arrives at periodic car inspection. Then, the inspection service provider performs the measurement process S3. In other words, the inspection unit A2 is connected to the subject electric wire (the electric wire 2) routed in the automobile for the wire inspection, and obtains the response signal. In the example mentioned in FIG. 1, as the measurement process S3, the characteristic impedance of the twisted pair wire is measured and a measurement result is obtained as the response signal.

After the measurement process S3 is completed, the analysis process S4 is performed. In the analysis process S4, the inspection service provider inputs the serial number of the subject electric wire into the analysis unit A3 as appropriate, so that the analysis unit A3 obtains individual identification information of the subject electric wire (C2) inspected by the inspection unit A2. Thereafter, the analysis unit A3 communicates with the memory unit A1 via the Internet or other means. Then, based on the individual identification information, the analysis unit A3 retrieves and read the response signal of the initial state for the subject electric wire (C2) from the response signals of many electric wires (C1 to C3) stored in the memory unit A1.

In the analysis process S4, the analysis unit A3 further compares the response signal (C2a) at the time of inspection obtained by the inspection unit A2 with the response signal (C2b) in the initial state retrieved from the memory unit A1. Then, after finding the subtraction between the two response signals, as appropriate, the determination is made as to whether or not a difference exists between the two response signals. If there is a difference between the two response signals that is more than a predetermined level such as an error or a negligible difference, the judge is made that damage occurs to the subject electric wire that did not exist in the initial state of the subject electric wire. On the other hand, if there is no difference between the two response signals more than the predetermined level, a judge is made that no problematic damage occurs to the subject electric wire. Furthermore, if possible in view of type of the electric wire or type the wire inspection, the analysis section A3 analyzes the result of the comparison of the response signals in more detail to identify the type and/or the damaged position.

### <Variation in Response Signal and Change Due to Damage>

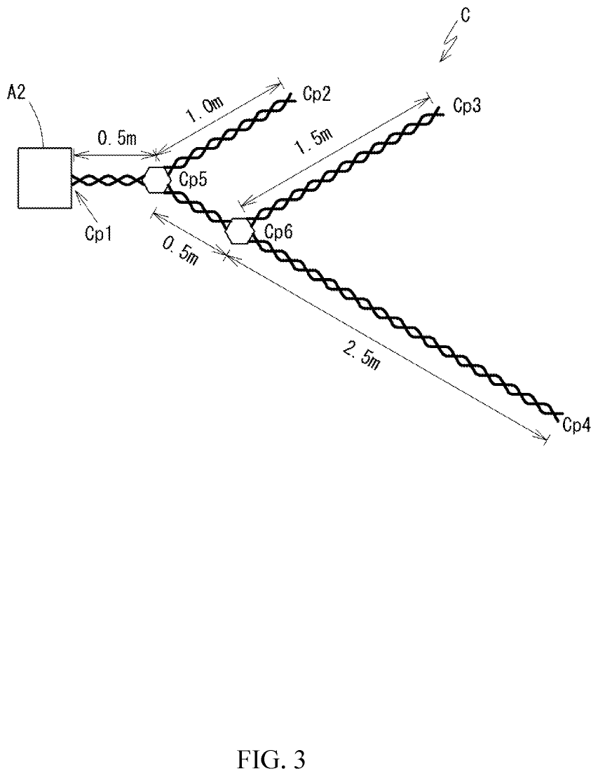

Next, the variation of the response signals of the individual electric wires and the change of the response signal due to damage are explained. Here, as an example, as shown in FIG. 3, an explanation is made for a case of measuring the characteristic impedance of the electric wire C in the form of the twisted pair wire with branches at two points (points Cp5 and Cp6) using the time domain reflectometry, indicating an example of actual measurement results. In addition, an example of the measurement indicated here is measured using a multi-carrier time domain reflectometry (MCTDR), which will be explained later.

FIG. 4A shows the characteristic impedance measured by the measurement device (the inspection unit) A2 connected to a base end Cp1 of the electric wire C with no damage. In FIG. 4A and the later-described FIGS. 4B-4E, the time axis is converted to a distance from the base end Cp1 (unit: m) on the horizontal axis and the characteristic impedance on the vertical axis. The characteristic impedance on the vertical axis is indicated by an amount of change with the value at the minimum distance being set to zero. A measurement result in FIG. 4A shows a large wave, even though there is no damage to the electric wire C. This wavy structure is mainly due to reflections at the two branched portions Cp5 and Cp6.

FIG. 4B shows a measurement result of the characteristic impedance for a short circuit formed between the two conductors at a base end Cp1 which is one end of the electric wire C, as a model of damage. In comparison with the measurement result in FIG. 4A, a change in the waveform is seen. The change is due to the formation of the short circuit at the base end Cp2. FIG. 4C shows a waveform of a subtraction between the waveform after the damage formation in FIG. 4B minus the waveform before the damage formation in FIG. 4A. In the waveform showing the subtraction, a large negative peak structure is seen in the vicinity of 1.5 m distance. This peak structure can correlates a change due to the damage formation. In fact, the base end Cp1 at which the short circuit was formed as damage, is 1.5 m away from the base end Cp1, corresponding to the position where the peak was observed in the subtraction.

Next, there will be shown the measurement results of the characteristic impedance for the electric wire (hereinafter, referred to as an “individual electric wire 1” which is the electric wire subject to be measured in FIG. 1A, and the electric wire (hereinafter, referred to as an “individual electric wire 2”) which is of the same type as the electric wire 1, i.e., another electric wire manufactured in the same manner based on the same design as the individual electric wire 1, both measured in the same manner with no damage. FIG. 4D shows measurement results of the characteristic impedance for the individual electric wires 1 and 2 together. Comparing waveforms of the two individual electric wires, although they are similar in trends of increasing and decreasing signal strengths in wave forms, they are different in details of signal waveforms, such as positions and sizes of peaks and troughs.

The subtraction between the waveforms of the individual electric wires 1 and 2 in FIG. 4D is shown in FIG. 4E. A large wavy structure is seen in a subtraction signal in FIG. 4E. Within the wavy structure, a negative peak structure similar to that observed in the vicinity of 1.5 m distance in FIG. 4C is observed in the vicinity of 2 m distance. In other words, it can be said that the subtraction between the measurement results obtained for the two different individual electric wires of the same type without damage indicates a similar peak structure in shape and intensity to the subtraction between the measurement results in presence and absence of damage to the identical electric wire.

This means that when attempting to detect damage of the electric wire based on the measurement results of the characteristic impedance, damage detection cannot be performed correctly unless comparing the measurement results in the presence and absence of damage to the identical electric wire. Even if the measurement result obtained for the individual electric wire 2 in the absence of damage is compared with that obtained for the individual electric wire 1 in the presence of damage, it is difficult to detect damage to the individual electric wire 1. However, even for the same type of the electric wire, it is possible to detect the presence or absence of damage and the damaged position by identifying the individual electric wire and comparing the measurement results between the initial state and at the time of inspection after time elapses from the initial state of the identical individual electric wire, as shown in FIG. 4C.

In the wire inspection system and the wire inspection method of the embodiment of the present disclosure described above, the response signals obtained for a plurality of the electric wires are stored in the memory unit A1 for the individual electric wire in the initial state, and at the time of inspection, for the subject electric wire to be inspected, the response signal in the initial state corresponding to the subject electric wire is retrieved from the memory unit A1. The retrieved response signal in the initial state is then compared with the response signal obtained at the time of inspection for the subject electric wire. Thus, by obtaining and storing the response signal in the initial state by identifying the electric wire for the individual electric wire, and comparing the response signals of the initial state and at the time of inspection for the individual electric wire subject to be inspected, it is possible to sensitively detect the presence of damage and identify the damaged position for the individual electric wire without being affected by variations in the response signals among the individual electric wires as shown in FIG. 4D, even when such variations exist. In particular, when there are a large number of the electric wires of the same type, if the response signals in the initial state are stored for the large number of the electric wires constituting the wire group, and if the response signal corresponding to each electric wire is retrieved and compared when the large number of the electric wires are inspected individually, highly accurate damage detection can be performed for each of the large number of the electric wires.

When the electric wire has elements that are discontinuous with the surroundings, such as the branches, as in the electric wire C shown in FIG. 3, the electrical signals are often reflected at the positions where these elements are formed, and the response signals often show behaviors similar to that of an area of damage. In such cases, the variations in the response signals from the individual electric wires can tend to be particularly large. Furthermore, if damage is minor, the peak structure or the like in the response signal originating from the damage may be buried in structures in the response signal originating from the discontinuous elements such as the branches, making them difficult to distinguish. In these cases, it is particularly useful in detecting damage by storing the response signal of the initial state for each electric wires and comparing it with the response signal at the time of inspection. Furthermore, the detection accuracy can be further improved by using a subtraction detection method, which finds the subtraction between the response signals in the initial state and at the time of inspection. This is because the contributions to the response signals from the discontinuous elements such as the branches can be at least partially canceled out by finding the subtraction, thus emphasizing the structure on the response signal due to damage.

Another method that can detect the occurrence of damage from the change between the response signals in the individual electric wires by eliminating variations in characteristics among the individual electric wires, it can be conceivable to keep the measurement devices connected to the individual electric wires at all times, continuously inputting the inspection signals and obtaining response signals, and continuously monitoring the change between the response signals. In this case, however, it is necessary to install the measurement devices for the individual electric wires, i.e., each vehicle equipped with the electric wire, which requires a large cost. In contrast, by using the wire inspection system and the wire inspection method of this embodiment, each inspection service provider only needs to own one measurement device as the inspection unit A2, except the use of the measurement device by the manufacturer who obtains initial data in the initial state. Then, each time when the wire inspection is performed, the measurement device is connected to the individual wire to obtain the response signal, and when the wire inspection is completed, the measurement device can be removed. In this way, it becomes possible to perform highly accurate inspections of the individual electric wires, while eliminating the effects of variations in characteristics and reducing the cost required for inspecting damage of the electric wire.

Furthermore, in the wire inspection system and the wire inspection method of this embodiment, information on the response signals in the initial state for a large number of the electric wires is accumulated in the common memory unit A1, which includes the manufacturer's information management server. Then, a large number of inspection service providers distributed over a wide area can access the common memory unit A1 via the internet, through their respective analysis units A3, and retrieve the response signal in the initial state of the electric wire subject to be inspected, from the response signals in the initial state of the large number of the electric wires stored in the memory unit A1. By having large-scale manufacturers acquire the response signals of the electric wires at the time of manufacturing or installing, and by identifying and centrally managing information on a large number of the electric wires by the individual electric wires and making the information available to the large number of inspection service providers distributed over a wide area, the processes of accumulation, management, and use of information on the characteristics of the electric wires can be efficiently carried out.

In the wire inspection system and the wire inspection method, the type of the inspection signal and the type of the response signal for performing the wire inspection can be set appropriately according to the specific construction of the damage detection unit provided with the electric wire, but it is preferable to use the electrical signal including alternate-current components as the inspection signal to measure electrical characteristics, such as characteristic impedance, in the time domain or the frequency domain. In this case, in addition to detecting the presence of damage in the electric wire, if any, the damaged position along an axial direction of the electric wire can be determined. In the response signals measured in the time domain or the frequency domain, an area on the response signals that differs between the initial state and at the time of inspection can be correlated to a position along the axial direction of the electric wire, and the judge is made that damage occurs at the position. In the case of a time-domain measurement, the time axis can be converted to a position on the electric wire based on the propagation velocity of the inspection signal. On the other hand, in the case of a frequency-domain measurement, information as to frequency can be converted to a position on the electric wire by inverse Fourier transforming the inspection signal obtained for the frequency axis.

In performing measurements in the time domain or in the frequency domain, the damaged position can be identified by measurement using either one of transmission and reflection methods, although the reflection method is particularly preferred. When performing measurements using the reflection method, it is not necessary to connect the measurement device to both ends of the electric wire, but only to one end of the electric wire, then the wire inspection can be performed. In this case, even when the electric wires are arranged in places that are not easily accessible, such as inside a vehicle, or when the electric wires take complicated paths, the wire inspections can be performed without removing the electric wires or removing obstacles, as long as the measurement device can be connected to one end of the electric wire. Next, in describing the electric wire wound with the conductive tape as the electric wire of the first embodiment of this disclosure, the measurement of characteristic impedance using the time domain reflectometry and the frequency domain reflectometry is also described in more detail.

### <Examples in the Form of Electric Wire>

The following is a specific example of an electric wire that can be suitably applied for inspection by the wire inspection system and the wire inspection method described above. Two types of electric wires are described in more detail here: an electric wire 1 wound with a conductive tape as the electric wire of the first embodiment of the present disclosure and an electric wire 3 wound with a laminated tape as the electric wire of a second embodiment of the present disclosure. For the two types of the electric wires 1 and 3, damage can also be detected using methods other than using the wire inspection system and the wire inspection method of the present disclosure. For example, there can also be applied damage detection by way of continuously inspecting the electric wires with the measurement devices connected at all times. Therefore, in the following, other matters related to the inspection method will be discussed as required.

[1] Electric Wire Wound with Conductive Tape

First, the electric wire 1 wound with the conductive tape will be described as the electric wire in accordance with the first embodiment.

(Structure of Electric Wire Wound with Conductive Tape)

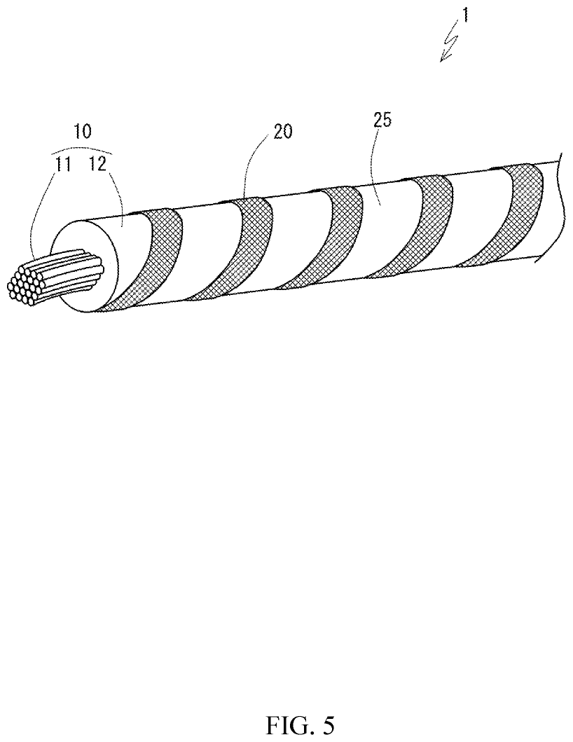

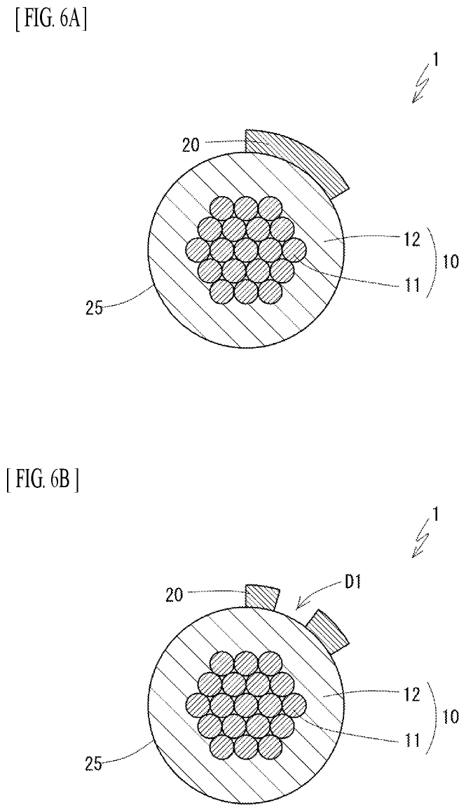

FIG. 5 shows a schematic view of the electric wire 1 wound with the conductive tape as the electric wire of the first embodiment of the present disclosure. Also FIG. 6A shows an example of a cross-section of the electric wire 1 wound with the conductive tape cut perpendicular to the axial direction.

(Structure of Electric Wire Wound with Conductive Tape)

The electric wire 1 wound with the conductive tape (hereinafter occasionally referred to simply as “electric wire”) 1 has a core wire 10 and a conductive tape 20 that is arranged around the outer circumference of the core wire 10. The core wire 10 is a main body of the electric wire 1 and is responsible for application of current and voltage between both ends as well as signal transmission. At the same time, the core wire 10 and the conductive tape 20 function as the damage detection unit in the form (iii) described above, and when external damage D is formed on a surface of the electric wire 1, the external damage D is detected by the damage of the conductive tape 20.

The core wire 10 has a conductor 11 made of along conductive material and an insulation coating 12 made of an insulating material covering an outer circumference of the conductor 11. The insulation coating 12 is exposed on the surface of the core wire 10 as a whole and is composed of the outer circumference of the core wire 10. In the form shown in a figure, the core wire 10 has a single wire structure including only one insulated wire with the insulation coating 12 on the outer circumference of the conductor 11. The conductive tape 20 is arranged in direct contact with the outer circumference of the insulation coating 12, which directly covers the outer circumference of the conductor 11.

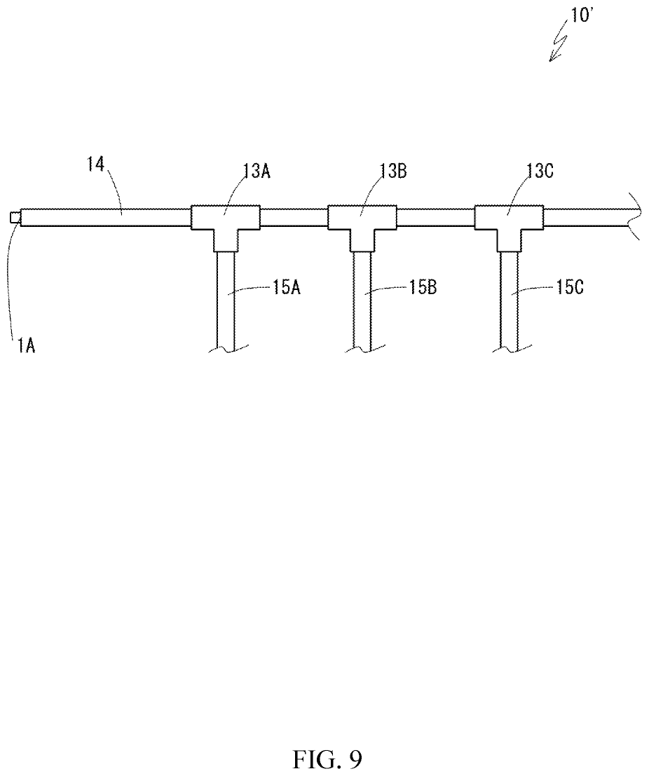

The structure of the core wire 10 is not limited to the single wire structure described above, but can be any structure as long as the core wire 10 including the conductor 11 and the insulation coating 12 covering the outer circumference of the conductor 11 and exposed on the surface. An existing electric wire can be used as it is as the core wire 10. In the core wire 10, the insulation coating 12 may cover the outer circumference of the conductor 11 directly or through other members. Further, the number and arrangement of the conductor 11 are not particularly limited. Examples of structures of the core wire 10 other than the single wire structure include a shielded cable in which a shielded conductor is arranged on the outer circumference of an insulated wire and the outer circumference thereof is covered with the insulation coating 12, and a pair cable in which the insulation covering 12 as an outer covering covers the outer circumference of a parallel-pair wire in which a pair of the insulated wires is arranged in parallel or a twisted pair wire in which a pair of the insulated wires is twisted together with each other. However, as will be explained in more detail later, it is more preferable for the core wire 10 to have a form which is susceptible to external noise, rather than a form in which the characteristic impedance can be measured between each component of the core wire 10 itself, similar to the single wire structure, and which is susceptible to external noise, in that the significance of detecting the external damage D by providing the conductive tape 20 is relatively higher. The core wire 10 may be in the form of a straight line, as shown in FIGS. 5, 8, and 10, or it may have the branched portions (13A-13C) in the middle, as shown in FIG. 9.

The conductive tape 20 is in the form of a tape body having conductivity. The conductive tape 20 is wound around the core wire 10 in a spiral manner along the axial direction of the core wire 10, in contact with the surface of the insulation coating 12 of the core wire 10. The conductive tape 20 is not tightly wound without gaps between adjacent turns in the spiral shape, in a close and superimposed manner, but is coarsely wound leaving gaps 25 that are not occupied by the conductive tape 20 between the adjacent turns. In the gaps 25 between the turns, the insulation coating 12 of the core wire 10 is not covered by the conductive tape 20 and is exposed on the surface of the electric wire 1 as a whole. In addition, as for a shape of the conductive tape 20, a tape body is referred to as a sheet-shaped member having thickness smaller than the width thereof, which is to be distinguished from a linear body, such as a metal wire.

The conductive tape 20 may be made of any material as long as it is conductive, but it is preferable to be made of a metallic material. In this case, the conductive tape 20 may be in the form of a metallic foil with the entire area thereof being in the form of a metallic material, or a layer of the metallic material formed on the surface of a base material. When the base material is used, the base material itself may be composed of an insulating material, such as an organic polymer material, as long as at least a layer of the metallic material is formed on the side of the base material opposite to a side that is in contact with the core wire 10. In either case, a type of the metallic material including the conductive tape 20 is not particularly limited, but copper or copper alloys, aluminum or aluminum alloys can be given as an example from the viewpoint of superior conductivity and strength. However, it is preferable not to use iron and iron alloys as the metallic material including the conductive tape 20, since severe oxidation of the metallic material may make it impossible to accurately detect damage by using the conductivity of the conductive tape 20 as a part of its principle. The conductive tape 20 may be fixed to the surface of the core wire 10 by bonding or fusing.

The thickness of the conductive tape 20 is also not particularly limited, but the thinner the tape, the greater the sensitivity in detecting damage in the electric wire 1. Specifically, it is preferable that the conductive tape 20 is thin to the extent of causing breakage due to the expected external damage D in the electric wire 1 or, not even to the extent of causing breakage, to the extent of forming the damage D1 of deep and in wide area to cause the change in the capacitance between the conductive tape 20 and the conductor 11. On the other hand, it is preferable that the conductive tape 20 has a thickness enough to have sufficient strength to ensure that the winding of the conductive tape 20 in the spiral shape does not cause problems.

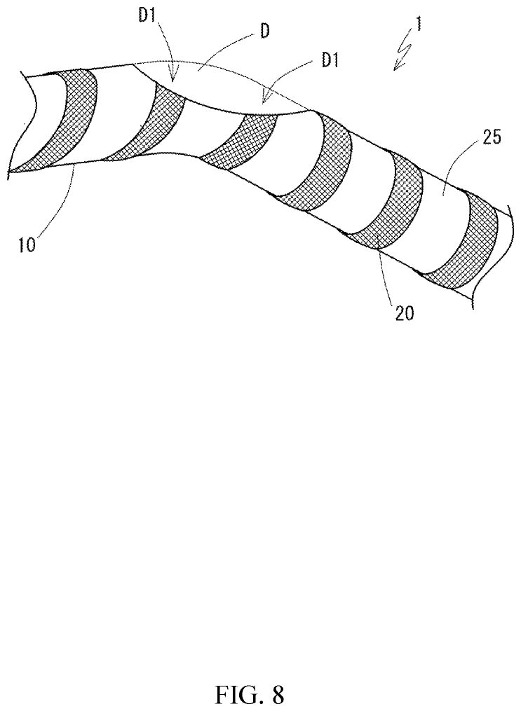

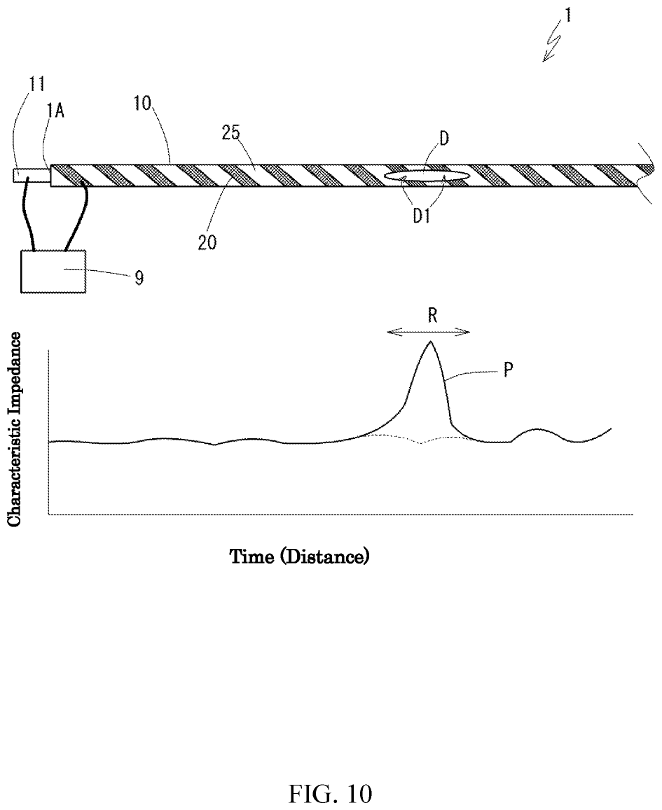

There is no particular limitation of the pitch of the spiral shape that the conductive tape 20 is composed around the outer circumference of the core wire 10 and the ratio of the width of the conductive tape 20 to the width of each of the gaps 25. However, as shown in FIG. 6A, it is necessary to wind the conductive tape 20 roughly enough, that is, with a sufficiently large pitch and width of each gap 25 relative to the width of the conductive tape 20, so that the conductive tape 20 does not cover the entire circumference of the core wire 10 but only some areas along the circumferential direction in the cross section cut perpendicular to the axial direction of the electric wire 1. It is more preferable that the percentage of the circumference of the core wire 10 that is not covered by the conductive tape 20 and is exposed as the gaps 25 should be 50% or larger, and more preferably 75% or larger. On the other hand, the pitch of the spiral shape should be small enough that the expected external damage D in the electric wire 1 occupies at least one pitch along the axial direction of the electric wire 1, as shown in FIGS. 8 and 10. In this case, even if the external damage D is formed at various positions in the axial and circumferential directions of the electric wire 1, the external damage D is more likely to overlap the area where the conductive tape 20 is arranged. For example, when the electric wire 1 is bent and arranged as shown in FIG. 8, the pitch of the spiral should be set to be less than ⅓ of the allowable bending radius of the electric wire 1.

It is preferable that the conductive tape 20 is exposed on the outer surface of the electric wire 1 as a whole, without being covered on the outer circumference by other components. It is because, when the electric wire 1 comes into contact or friction with other objects, damage D1 tends to occur on the conductive tape 20, increasing the sensitivity in damage detection. However, a layer composed of the organic polymer or similar material may cover the conductive tape 20, as long as the layer is thin enough to be easily damaged by contact or friction with other objects.

In the electric wire 1, the conductive tape 20 may be provided over the entire area or only in some areas along the axial direction of the core wire 10. It is preferable to employ the form in which the conductive tape 20 is provided with the entire area in that it can detect the external damage D along the axial direction of the electric wire, regardless of the position of the external damage D, while it is preferable to employ the form in which the conductive tape is provided only in some areas in that it can suppress an increase in manufacturing cost and mass of the electric wire 1 for providing the conductive tape 20. When the conductive tape 20 is provided only in some areas, it is preferable to provide the conductive tape 20 including areas where the external damage D is likely to occur due to contact or friction with other members, such as where bending is applied to the core wire 10. As shown in FIG. 9, even when the core wire 10 has the branched portions 13A to 13C in the middle thereof, if there is an area on a tip side than any of the branched portions 13A to 13C (when a side to which a measurement device 9 described below is connected is defined as the base end 1A, the opposite side thereof) where the external damage D is likely to occur, it is preferable that the conductive tape 20 is provided to include the area on the tip side than the branched portion.

The use of the electric wire 1 is not limited, and it can be routed in any equipment, such as a vehicle, or equipped in any building. However, the electric wire 1 should be used in a floating state, with the conductive tape 20 not electrically connected to the earth potential (ground potential). It is because, by keeping the conductive tape 20 in the floating state, such as on/off control when a switch is provided between the core wire 10 and the ground potential, the state of electrical connection between the conductor 11 and the ground potential is unlikely to affect the detection of the external damage D using conductive tape 20.

### (Wire Inspection Method)

Next, the wire inspection performed on the electric wire 1 wound with the conductive tape will be explained. In wire inspection, while directly detecting the damage D1 occurs to the conductive tape 20, the object of the wire inspection is to detect that external damage D formed on the insulation covering 12 of the core wire 10, or that the premonitory stage just before a formation of the external damage D is reached on the insulation covering, using the damage D1 on the conductive tape 20 as an indicator.

In the wire inspection, the characteristic impedance between the conductor 11 and the conductive tape 20 are measured. Then, the characteristic impedance obtained as the response signals are compared e between the response signals in the initial state and at the time of inspection to determine the presence or absence of the external damage D formed on the electric wire 1 at the time of inspection. More preferably, it is also identify the position where the external damage D is formed along the axial direction of the electric wire.

As shown in FIG. 10, the wire inspection is performed by connecting the measurement device 9 (corresponding to the inspection unit A2) at the base end 1A of the electric wire 1 as appropriate, and the characteristic impedance between the conductor 11, which constitutes the core wire 10, and the conductive tape 20 is measured. It is preferable that the measurement of the characteristic impedance is performed by the time domain reflectometry (TDR method) or the frequency domain reflectometry (FDR method).

Here, in relation to the wire inspection, an explanation will be made as to the relationship of the characteristic impedance between the conductor 11 and the conductive tape 20, to the external damage D of the electric wire 1. FIGS. 6A and 6B show cross sections of the electric wire 1. In FIG. 6A, no damage D1 occurs to the conductive tape 20, while in FIG. 6B, the damage D1 occurs to the conductive tape 20 at a position corresponding to the cross section shown in the figure due to the external damage D to the electric wire 1. The damage D1 formed on the conductive tape 20 does not necessarily being enough to form breakage of the conductive tape 20; however, here, for clarity, there is shown in the cross section that a part of the conductive tape 20 is broken.

The conductive tape 20 covering the outer circumference of the core wire 10 and the conductor 11 including the core wire 10 face each other with the insulation coating 12 made of the insulating material (dielectric) interposed therebetween, and capacitance is defined between the conductive tape 20 and the conductor 11. The capacitance has a positive correlation with the area of the conductive material facing each other across the dielectric. Therefore, the capacitance is smaller when the damage D1 is formed on the conductive tape 20, as shown in FIG. 6B, than when the damage D1 is not formed on the conductive tape 20, as shown in FIG. 6A. The characteristic impedance between the conductive tape 20 and the conductor 11 is greatly affected by the capacitance between the conductive tape 20 and the conductor 11. Therefore, if the capacitance between the conductive tape 20 and the conductor 11 changes due to the damage D1 occurring to the conductive tape 20, the characteristic impedance between the conductive tape 20 and the conductor 11 is to be changed.

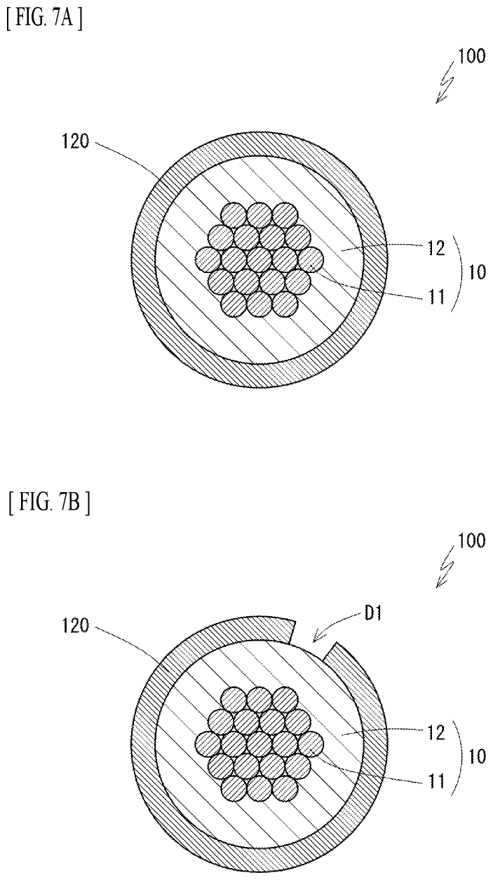

An electric wire 100 shown in FIG. 7A has a conductive layer 120 in the form of a continuous layer of the conductive material all around the outer circumference of the core wire 10, and even when the conductive layer 120 is formed on the entire circumference of the core wire 10, if the damage D1 occurs to the conductive layer 120 as shown in FIG. 7B, theoretically, the magnitude of the capacitance between the conductive layer 120 and the conductor 11 of the core wire 10 can be changed, as in FIG. 6B. Assuming if the external damage D is formed over almost the entire circumference of the electric wire 100 and the damage D1 also occurs over almost the entire area of the conductive layer 120 in the circumferential direction, the capacitance between the conductive layer 120 and the conductor 11 is significantly changed, the characteristic impedance between the conductive layer 120 and the conductor 11 is to be significantly changed. In practice, however, it is rare for external damage to occur over almost the entire circumference of the electric wire. In many cases, the external damage D caused by contact or friction with external objects is formed by occupying only a part of the area along the circumferential direction of the electric wire 1, yet forming over some length along the axial direction of the electric wire 1, as shown in FIGS. 8 and 10. If such external damage D is formed which occupies only a part of the area along the circumferential direction of the electric wire 1, and if the conductive layer 120 covers the entire circumference of the core wire 10 as shown in FIG. 7A, then the percentage of the conductive layer 120 as a whole shared by the damage D1 becomes smaller, and a rate of change in capacitance (a ratio of the amount of change to the initial state) associated with the occurrence of the damage D1 becomes small. As a result, the rate of change in the characteristic impedance associated with the formation of the damage D1 also becomes small. Then, even if an attempt is made to detect the occurrence of the damage D1 by detecting the change in the characteristic impedance, it becomes difficult to sensitively perform the detection.

On the other hand, if the conductive tape 20 is roughly wound around the circumference of the core wire 10 with the gaps 25 being left between the turns as shown in FIG. 5, and the conductive tape 20 occupies only an area of the circumference of the core wire 10 in cross section as shown in FIG. 6A, the ratio of the area shared by the damage D1 to the area covered by the conductive tape 20 in the initial state increases when the damage D1 is formed on the conductive tape 20 as shown in FIG. 6B. Then, the change rate of the capacitance between the conductive tape 20 and the conductor 11 becomes large. As a result, the change rate of the characteristic impedance between the conductive tape 20 and the conductor 11 becomes large, and by detecting the change in the characteristic impedance, the sensitive detection of the formation of the damage D1 becomes possible. Even when the external damage D is formed only in a part of the area along the circumferential direction of the electric wire 1, if the external damage D causes the formation of the damage D1 to the conductive tape 20, the event is sensitively reflected as a change in characteristic impedance, and the formation of the external damage D can be detected. Further, even if the damage D1 is minor, it is more likely to be detected.

However, under the arrangement of the conductive tape 20 being roughly wound around the circumference of the core wire 10, and the gaps 25 that are not covered by the conductive tape 20 being exist between the turns, if the external damage D is formed only in a part of the area along the circumferential direction of the electric wire 1 as shown in FIGS. 8 and 10, and if the extremely short length of the external damage D is formed along the axial direction of the electric wire 1, it is possible that the external damage D does not reach to a position where the conductive tape 20 is arranged and the damage D1 is not formed on the conductive tape 20. However, when the external damage D is formed on the electric wire 1 by contact or friction with external objects, the external damage D is, in many cases, formed along the longitudinal direction of the electric wire 1 over some length. For example, as shown in FIG. 8, when the electric wire 1 is routed in an automobile in a bent state, an outer part of the bend in the electric wire 1 may contact an object (such as a body of an automobile) in the vicinity, possibly causing the external damage D being formed. In this case, the damage D is often formed in an area of the bent over a certain length by contact with the external objects. Therefore, if the pitch of the spiral is set so that the length of the expected external damage D is sufficiently long relative to the pitch of the spiral shape of the conductive tape 20, the external damage D is to be reached at any position within the length of the external damage D, and cause the damage D1 to the conductive tape 20. Then, through the change in capacitance, the change in the characteristic impedance between the conductive tape 20 and the conductor 11 appears, and the occurrence of the damage D1 can be detected.

As described above, by winding the conductive tape 20 around the outer circumference of the core wire 10 in a rough spiral, with the gaps 25 between the turns, the occurrence of the external damage D can be sensitively detected by detecting the change in characteristic impedance between the conductive tape 20 and the conductor 11 when the external damage D occurs in the electric wire 1. The fact that the damage D1 is occurred to the conductive tape 20 wound around the circumference of the core wire 10 means that there is a high probability that the external damage D is also occurred to the insulation coating 12 of the core wire 10. By detecting the damage D1 formed on the conductive tape 20, it is possible to detect that the external damage D is formed on the core wire 10 as a body part of the electric wire 1, or that the premonitory stage of the formation of the actual external damage D is reached. As shown in FIG. 10, when the damage D1 of the conductive tape 20 is formed as breakage in the straight electric wire 1, the change in characteristic impedance is shown in a direction increasing the value in accordance with the formation of the damage D1. However, the change of the characteristic impedance may occur in either direction of increasing and decreasing, depending on the type and shape of the electric wire 1, or the form and shape of the damage D1.

As described above, although it is possible to detect the occurrence of the external damage D in the electric wire 1 by examining the occurrence of the change in characteristic impedance between the conductive tape 20 and the conductor 11 in the electric wire 1, it is possible to identify not only the presence or absence of the external damage D but also the position of the external damage along the axial direction of the electric wire 1 by measuring the characteristic impedance by the TDR or FDR methods. As shown in FIG. 10, when the characteristic impedance between the conductive tape 20 and the conductor 11 is measured at a side of the base end 1A of the electric wire 1, the variation of the characteristic impedance is obtained as a function of time, as the measurement result by the TDR method, while the variation of the characteristic impedance is obtained as a function of frequency, as the measurement result by the FDR method. In either case, if the damage D1 occurs in the conductive tape 20 at the middle of the electric wire 1 in the axial direction, the inspection signal is reflected at a position of the damage D1. Then, the characteristic impedance changes discontinuously at the position corresponding to the damage D1 on the time or frequency axes. Therefore, in the measurement result obtained by the TDR or FDR methods, the value of the characteristic impedance changes discontinuously from the values in the surrounding areas. Then, in the measurement result obtained by the TDR or FDR methods, a change area R is detected in an area where the value of the characteristic impedance changes discontinuously from the values in the surrounding areas, or where the value of the characteristic impedance changes from the value of the previous measurement, an initial state, for example. Further, the judgement can be made that the external damage D is formed at the position on the electric wire 1 that corresponds to the change area R. In this way, not only the presence or absence of the external damage D on the electric wire 1, but also the position of the formation of the external damage D can be identified.

FIG. 10 schematically shows a relationship between the external damage D formed on the electric wire 1 and the measurement result obtained in the case where the TDR method is used. The upper part of the figure shows the electric wire 1 with the external damage D, and the lower part shows an example of the measurement result obtained by the TDR method for the electric wire 1. In the measurement result, the solid line shows a case where the external damage D is formed on the electric wire 1, and the dashed line shows a case where the external damage D is not formed on the electric wire 1.

In the TDR method, the distance from the base end 1A and the value in the time axis are proportional. In FIG. 10, while the measurement result shows time on the horizontal axis and the measured characteristic impedance on the vertical axis, a peak P, which rises discontinuously from the surrounding area, is observed in the area corresponding to the distance from the base end 1A to the area where the external damage D is formed on the electric wire 1. Although there are also small peak-like structures in the surrounding areas that originate from noise or other elements other than the external damage to the electric wire 1, if the core wire 10 is in the form of a simple straight line, the height of the peak P originating from the external damage D is often obviously larger than the peak-like structures unrelated to the external damage D. Further, the measured value obtained in the area where the peak P originating from the external damage D occurs is increased compared with the value, indicated by the dotted line, in the initial state where no external damage D is formed. Thus, if the detection of the change area R in the horizontal axis is made for the area where the value of the characteristic impedance changes discontinuously compared to the values in the surrounding areas, or where the value of the characteristic impedance changes from the value in the initial state, the position of the change area R can be correlated to the position of the external damage D from the base end 1A on the electric wire 1. In other words, through the characteristic impedance measurement, it is possible not only to detect the presence of the external damage D, but also to identify the position of the external damage D formed along the axial direction of the electric wire 1. As shown in examples described later, the position of the external damage D can be accurately identified within an error range of approximately 200 mm or less. Although the drawings are not posted, the area of the external damage D formed along the axial direction of the electric wire 1 can be identified also by the FDR method by detecting the change area R as the area where the value of the characteristic impedance changes discontinuously compared to the values in the surrounding areas or where the value of the characteristic impedance changes from the initial state, with the horizontal axis being as the frequency. In this case, the characteristic impedance is obtained as the function of frequency and can be converted into information on the distance from the base end 1A of the electric wire 1, by performing an inverse Fourier transform.

When using the TDR method, the inspection signal input to the base end 1A of the electric wire 1 is typically a pulse square wave. However, as an advanced form of the TDR method, it is also preferable to use an inspection signal in which components of different frequencies are superimposed with a predetermined intensity to forma predetermined waveform other than the square wave. Specifically, although the inspection signal includes a superimposition of the components existing over a continuous frequency range and having mutually independent intensities, it is possible to use such an electric signal in the continuous frequency range that the components of some frequencies (excluded frequencies) have no intensities or discontinuously smaller intensities than the components at adjacent frequencies. A form of using the inspection signal with such excluded frequencies is known as the multicarrier time domain reflectometry method (Multicarrier Time Domain Reflectometry MCTDR method), which is disclosed, for example, in U.S. Patent Application Publication No. 2011/035168. In the inspection signal, setting of the intensity of each frequency component as well as setting of the excluded frequencies can reduce the influence of measurement noise and allow measurement of the reflected component.

For example, when the electric wire 1 is routed to the environment where other communication devices or communication wires exist in the vicinity such as inside an automobile, electromagnetic waves originating from the generation source external to the electric wire 1 are in a state of propagating around the electric wire 1. In this case, the exclusion frequencies are set so as to include the frequencies of these electromagnetic waves, and a contribution in the inspection signal is eliminated or reduced, so that the components having these frequencies are less likely to affect the result of the characteristic impedance measurement. As a result, the electromagnetic waves propagating in the vicinity of the electric wire 1 are less likely to impart noise to the measurement result of the characteristic impedance in the electric wire 1, and the detection of the external damage D in the electric wire 1 can be performed sensitively and with high accuracy. It is said that the MCTDR method is a measurement method which has both of the advantage of the TDR method such as a position that the correlation between the measurement result and the position where the external damage D is formed can be directly performed and the advantage of the FDR method such as resistance to noise.

When the change in the characteristic impedance due to the external damage D is significant in detecting the external damage D of the electric wire 1 by the TDR method including the MCTDR method or the FDR method, the external damage D can be detected based on the measurement result itself obtained by measuring the characteristic impedance. That is, the peak P corresponding to the external damage D can be detected by seeing the measurement result itself to find an area in which the value discontinuously changes as compared with the surrounding area, or by comparing the measurement result with the previous measurement result such as the initial state to find a position where the value changes between both. However, the peak P originating from the external damage D is buried in the peak structure or noise originating from the element other than the external damage D, for example, such as when the external damage D is minor, the electric wire 1 is long, and the electric wire 1 is branched, as a core wire 10′ shown in FIG. 9, so that the peak P may not also be able to be clearly recognized only by directly seeing the measurement result. In such a case, the subtraction detection method should be used. That is, a subtraction between the measurement result of the characteristic impedance in the initial state and the measurement result of the characteristic impedance after time elapses from the initial state should be calculated, an area in which the subtraction value discontinuously changes from the value in the surrounding area should be detected as the change area R, and the change area R should be correlated to a position where the external damage D exists.

As described above, in the electric wire 1 wound with the conductive tape, the core wire 10 may be constituted of an electric wire of any type, but is, most preferably, constituted of the single wire structure. This is because it can also be considered that in the case of the shielded cable and the paired cable, as described above as the form (i), the detection of the external damage D is performed by measuring characteristic impedance between the central conductor and the shielded conductor or between the mutual pair wires, while in the case of the single wire structure, the detection of the external damage D using the characteristic impedance is enabled for the first time only by winding the conductive tape 20 around the external portion since the core wire 10 has only the conductor 11 as the conductive member. Also, the single wire structure is excellent in the effect by which the influence of noise is reduced by winding the conductive tape 20, thereby enabling the external damage D to be detected with high sensitivity. That is, in the case of the shielded cable and the paired cable, the structure for reducing the influence of noise is included therein, and stable characteristic impedance is thus easily obtained, while in the case of the single wire structure, the characteristic impedance between the conductor 11 and the earth potential becomes very unstable. However, with the single wire structure as the core wire 10, by winding the conductive tape 20 around the outer circumference of the core wire 10, the characteristic impedance is stabilized. By performing the detection of the external damage D in a state where the characteristic impedance is stable in such a way, the change in the characteristic impedance value can be detected with high sensitivity, and can be correlated to the formation of the external damage D.

Further, as described above, the conductive tape 20 is distinguished from a wire body, and in the electric wire 1 according to this embodiment, the conductive tape 20 constituted exclusively of the tape body is used, but even if in place of the conductive tape 20, a conductive wire body such as a metal wire is wound in a rough spiral, the detection of the external damage D can be achieved. However, when the wire body is used, the difference in capacitance becomes too large, on the outer circumference of the core wire 10, between the position where the conductive material is arranged and the position where the conductive material is not arranged, and the characteristic impedance becomes unstable. As a result, it becomes difficult to detect the external damage D at a high position resolution. For such a reason, the conductive tape 20 constituted as the tape body, not as the wire body such as the metal wire, is used.

When the detection of the external damage D by the measurement of the characteristic impedance is performed while the electric wire 1 is routed to the device, it is preferable to perform the measurement of the characteristic impedance by the inspection signal in a static state where voltage or current other than the inspection signal is not applied to the electric wire 1 to be inspected, in that the sensitivity and the accuracy of the inspection is increased. Even the wire inspection system and the wire inspection method described above basically perform the wire inspection in the static state in such a way. However, the measurement of the characteristic impedance can be performed also in a state where voltage or current other than the inspection signal is applied to the electric wire 1. For example, the measurement of the characteristic impedance and the detection of the external damage D based on the measurement result can be continuously performed while the electric wire 1 is used in a state where current or voltage according to the original application of the core wire 10 is applied, with the measurement device 9 connected to the electric wire 1 at all times. Then, the formation of the external damage D is monitored in real time while the electric wire 1 is used, and it is possible to immediately detect that the external damage D is formed or that the premonitory stage of the external damage formation is reached. For example, when the core wire 10 has the single wire structure, the core wire 10 is often used for the application of direct current or direct voltage, but in that case, by inputting the inspection signal including the alternate-current component, the measurement of the characteristic impedance can be suitably performed even while the application of the current or the voltage to the conductor 11 is continued.

[2] Electric Wire Wound with Laminated Tape

Next, as the electric wire according to the second embodiment, the electric wire 3 wound with the laminated tape will be described. Here, the description of a structure and an inspection method common to the electric wire 1 wound with the conductive tape and effects by them is omitted, and the electric wire 3 wound with the laminated tape will be briefly described.

(Structure of Electric Wire Wound with Laminated Tape)

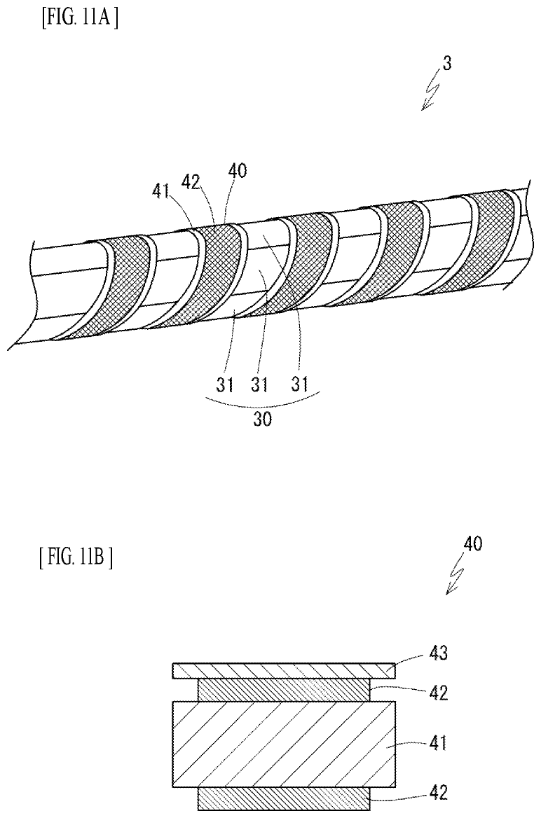

FIG. 11A shows a perspective view of an outline of the electric wire 3 wound with the laminated tape. In the electric wire 3 wound with the laminated tape, a laminated tape 40 is wound in a spiral manner around an outer circumference of a core wire 31. Similarly to the conductive tape 20, the laminated tape 40 may also be wound around an outer circumference of one core wire 31, but as shown in FIG. 11A, it is preferable that the laminated tape 40 be wound around an outer circumference of a wire harness 30 as a whole with a plurality of core wires 31 made into a bundle. In this case, the electric wire 3 wound with the laminated tape goes into a state of the wire harness wound with the laminated tape, but in this specification, is referred to as the electric wire 3 wound with the laminated tape by also including such a state. The laminated tape 40 may be directly wound around the outer circumference of the bundle of the core wires 31 (electric wire bundle), or the electric wire bundle may be accommodated in an outer covering material such as a tube to wind the laminated tape 40 around an outer circumference of the outer covering material.

As shown in a cross-sectional view (a cross section orthogonal to the tape longitudinal direction) in FIG. 11B, the laminated tape 40 is constituted such that coating layers 42, 42 are conductive and are respectively formed on both sides of a base material 41 which is a tape-shaped insulator or a semiconductor. In the laminated tape 40, the coating layers 42, 42 provided on both sides function as the two conductive members in the damage detection unit in the above (ii) form.

In the laminated tape 40, the constituting material of the base material 41 is not particularly limited as long as it is the insulator or the semiconductor, but the tape-shaped insulator having flexibility is preferably used. As a preferable example of the constituting material of the base material 41, a nonwoven cloth tape and a polymer tape can be given as an example. From the viewpoint that distancing is secured between the two coating layers 42, 42 to easily perform the damage detection by the change in impedance, the base material 41 preferably has some degree of thickness, and from the viewpoint, the base material 41 is particularly preferably formed of the nonwoven cloth tape. Alternatively, as the base material 41, a functionality material can also be used. The functionality material changes the electrical characteristics such as a dielectric constant, depending on the external environment such as temperature and humidity. For example, with the use of a moisture absorbing polymer sheet as the base material 41, when the base material 41 touches water, the dielectric constant and the conductivity at the position change, so that the impedance changes.

Also, the material constituting the coating layers 42, 42 is not particularly limited as long as it is the conductive material, but a metal such as copper or a copper alloy or aluminum or an aluminum alloy can be suitably used. As the method for forming the coating layers 42, 42 on both sides of the base material 41, metal sheet adhesion, metal vapor deposition, or plating can be given. The thickness of the coating layers 42, 42 is not particularly limited, but should be small to the extent of causing breakage or a short circuit due to external damage assumed in the electric wire 3 wound with the laminated tape and of causing the change in the characteristic impedance to sufficiently occur.

On the face of one coating layer 42, an adhesive tape 43 can be provided as appropriate. The laminated tape 40 can be fixed into a state of being wound around the outer circumference of the wire harness 30 by using the adhesive tape 43. When the laminated tape 40 is directly wound around the outer circumference of the electric wire bundle constituting the wire harness 30, the electric wire bundle is pressed by the laminated tape 40 through the adhesive tape 43, so that the laminated tape 40 is also enabled to have both of a role as the damage detection unit and a role as a binding material preventing the separation of the electric wire bundle.

In the forms shown in FIGS. 11A, 11B, the coating layers 42, 42 are not formed at both ends in the width direction of the laminated tape 40, and the point at which the base material 41 is exposed is provided, but the base material 41 is not necessarily required to be exposed in this way, and the coating layers 42, 42 may be provided on the entire surface of the base material 41. However, by leaving, at both ends in the width direction of the base material 41, the areas in which the coating layers 42, 42 are not provided, it is possible to prevent the situation where the coating layers 42, 42 on both sides come into contact with each other at the positions of the end edges of the laminated tape 40 to cause an unintended short circuit. Also, when the base material 41 is made of the functionality material which changes the electrical characteristics depending on the external environment, the base material 41 is exposed, and is directly contacted with the external environment, so that the base material 41 sensitively reflects the change in the external environment to be likely to cause the change of the electrical characteristics.

In the electric wire 3 wound with the laminated tape, the laminated tape 40 is wound in a spiral manner around the outer circumference of the wire harness 30 constituted as the electric wire bundle. Unlike the conductive tape 20 in the electric wire 1 wound with the conductive tape, gaps are not required to be provided between the turns of the spiral structure. The laminated tape 40 may be wound without providing the gaps between the turns, or the laminated tape 40 may be wound while the gaps each having a width smaller than the length of damage assumed are provided. The layer of the laminated tape 40 is preferably exposed on the outer surface of the electric wire 3 as a whole wound with the laminated tape.

### (Wire Inspection Method)

In the electric wire 3 wound with the laminated tape, the two conductive coating layers 42, 42 that the laminated tape 40 has are used as the damage detection unit, and characteristic impedance between the two coating layers 42, 42 is measured as the wire inspection, so that damage can be detected. In the wire inspection, while damage which occurs in the coating layers 42, 42 of the laminated tape 40 is directly detected, the purpose of the wire inspection is to detect that external damage is formed in the core wire 31 (or the wire harness 30), or that it is in the premonitory stage just before the external damage is formed, by using the damage in the coating layers 42, 42 as an indicator.

In a state where damage is not formed in the electric wire 3 wound with the laminated tape, the two coating layers 42, 42 constituting the laminated tape 40 respectively exist as conductive continuous bodies along the longitudinal direction of the laminated tape 40 in a state where they are insulated from each other by the base material 41, and have conductance determined by the material qualities or thicknesses of the base material 41 and the coating layers 42, 42. Here, when damage occurs in the laminated tape 40 and the conductance between the two coating layers 42, 42 changes, the change in the conductance component is observed as the change in the characteristic impedance between the two coating layers 42, 42. For example, it is assumed that at least one (usually, the coating layer directed to the outside) of the two coating layers 42, 42 causes breakage in the middle portion in the longitudinal direction of the laminated tape 40 such as when the electric wire 3 wound with the laminated tape causes contact or friction between the electric wire 3 wound with the laminated tape and the external object. Then, the conductance between the two coating layers 42, 42 decreases, and the characteristic impedance increases.

As the damage of the laminated tape 40, a short circuit between the two coating layers 42, 42 is assumed, other than the breakage of the coating layers 42, 42. For example, when a sharp conductor such as a metal piece is pierced into the laminated tape 40 from the outside, and is penetrated through the laminated tape 40, the two coating layers 42, 42 are short circuited through the conductor. Or, also when the laminated tape 40 undergoes severe friction or pressure to cause breakage or damage to the point of the layer of the base material 41 and the coating layers 42, 42 on both sides of the base material 41 locally come into contact with each other not through the base material 41, a short circuit can occur. When the short circuit occurs, the conductance between the two coating layers 42, 42 increases, and the characteristic impedance decreases.

In this way, as the wire inspection, the characteristic impedance between the two conductive coating layers 42, 42 constituting the laminated tape 40 is measured, and the characteristic impedance obtained as the response signal is compared between the response signals in the initial state and at the time of inspection, so that damage can be detected in the core wire 31 (or the wire harness 30) around which the laminated tape 40 is wound. That is, when a difference occurs between the characteristic impedance in the initial state and the characteristic impedance at the time of inspection occurs, it is possible to detect that damage occurs in the core wire 31 (or the wire harness 30) around which the laminated tape 40 is wound, or that it is in the premonitory stage just before the damage is formed. Further, when the electric wire 3 wound with the laminated tape has a relatively simple structure such as a straight-line shape, the type of damage can also be estimated according to the direction of the change in the characteristic impedance. When the characteristic impedance changes in the increasing direction, it is possible to estimate that damage so as to cause breakage in the coating layers 42, 42 of the laminated tape 40 occurs, and when the characteristic impedance changes in the decreasing direction, it is possible to estimate that damage so as to cause a short circuit between the coating layers 42, 42 occurs.

Also in the electric wire 3 wound with the laminated tape, by using the subtraction detection method as appropriate, as in the electric wire 1 wound with the conductive tape described above, the damage detection can be performed sensitively and with high accuracy also such as when the change in the response signal is small and when other than damage, the element providing change to the response signal such as the branch exists. Also, by using the TDR method including the MCTDR method or the FDR method, as in the electric wire 1 wound with the conductive tape, it is also possible to perform the discrimination, not only of the presence and absence of damage, but also of a position where damage is detected.

In the electric wire 3 wound with the laminated tape, when the base material 41 constituting the laminated tape 40 is made of the functionality material and changes the electrical characteristics depending on the external environment such as temperature and humidity, not only physical damage causing breakage or a short circuit in the coating layers 42, 42, but also the change caused depending on the external environment such as exposure to water can be detected as damage. This is because when the electrical characteristics such as the dielectric constant of the base material 41 changes due to the change in the external environment, the characteristic impedance between the two coating layers 42, 42 also changes. On the other hand, when only the physical damage is desired to be detected without being affected by the external environment, a material in which the change in the electrical characteristics depending on the environment is small should be used as the base material 41.

Also, the case where the base material 41 is made of the insulator has been mainly described here, but likewise, for the case where the base material 41 is made of the semiconductor, the wire inspection can be executed to detect damage. Further, in the form in which the base material 41 is made of the semiconductor, when monitoring is continued with the measurement device connected to the two coating layers 42, 42 of the laminated tape 40 at all times, the sensitivity of the damage detection can be increased by using the fact that the base material 41 is the semiconductor. Specifically, the characteristic impedance between the two coating layers 42, 42 should be measured in a state where low voltage to the extent of not causing a short circuit is applied through the base material 41 to between the two coating layers 42, 42. In this state, when the laminated tape 40 undergoes pressure to cause dielectric breakdown between the two coating layers 42, 42, a short circuit occurs between the two coating layers 42, 42, and is detected as the change in the characteristic impedance. Thus, it is possible to sensitively detect even damage to the extent of not reaching a short circuit due to the physical mutual contact between the two coating layers 42, 42.

Unlike the electric wire 1 wound with the conductive tape described above, the electric wire 3 with the laminated tape does not use the component of the core wire 31 as the damage detection unit, and constitutes the damage detection unit only by the component of the laminated tape 40 provided to be separated from the core wire 31. For the tape structure, the laminated tape 40 used here is more complicated than the conductive tape 20, but not by using the component of the core wire 31 as the damage detection unit, a damage detection function can be provided regardless of the type and form of the core wire 31. That is, as long as the laminated tape 40 can be wound on the outer circumference, the damage detection unit can be formed to the core wire and the wire harness of various structures and types. Further, since the damage detection using the laminated tape 40 does not use the component of the core wire and the wire harness, the laminated tape 40, when wound around any long member other than the electric wire and the wire harness, can be used for the damage detection with respect to the member as above.

### EXAMPLES

Examples will be given below. Note that the present invention is not limited to these examples.

[1] For Electric Wire Wound with Conductive Tape

First, for an electric wire wound with a conductive tape, it was confirmed whether the detection of damage by the measurement of characteristic impedance could be performed.

### [1-1] External Damage Detection in Straight Electric Wire

First, in a straight electric wire wound with a conductive tape, it was confirmed whether the detection of external damage could be performed by using the measurement of characteristic impedance.

### (Preparation of Specimen)

As a core wire, an electric wire having the single wire structure with an overall length of 10 m was prepared. A conductive tape made of a copper foil was wound in a rough spiral around an outer circumference of the core wire to make a specimen electric wire. The pitch of the spiral was 10 mm. The ratio of the width of the conductive tape to the width of each of gaps not occupied by the conductive tape was approximately 1.1.

In the specimen electric wire, simulated external damage was formed at a position at a predetermined distance from the base end. That is, at the predetermined position, the conductive tape was broken at one position. The position to form the simulated external damage was changed along the axial direction of the electric wire to prepare a plurality of specimen electric wires.

### (Detection of External Damage)

At the base end of each specimen electric wire prepared above, characteristic impedance between the conductor of the core wire and the conductive tape was measured. The measurement was performed by the MCTDR method. During the measurement, the potential of the conductive tape was kept in the floating state.

### (Results)

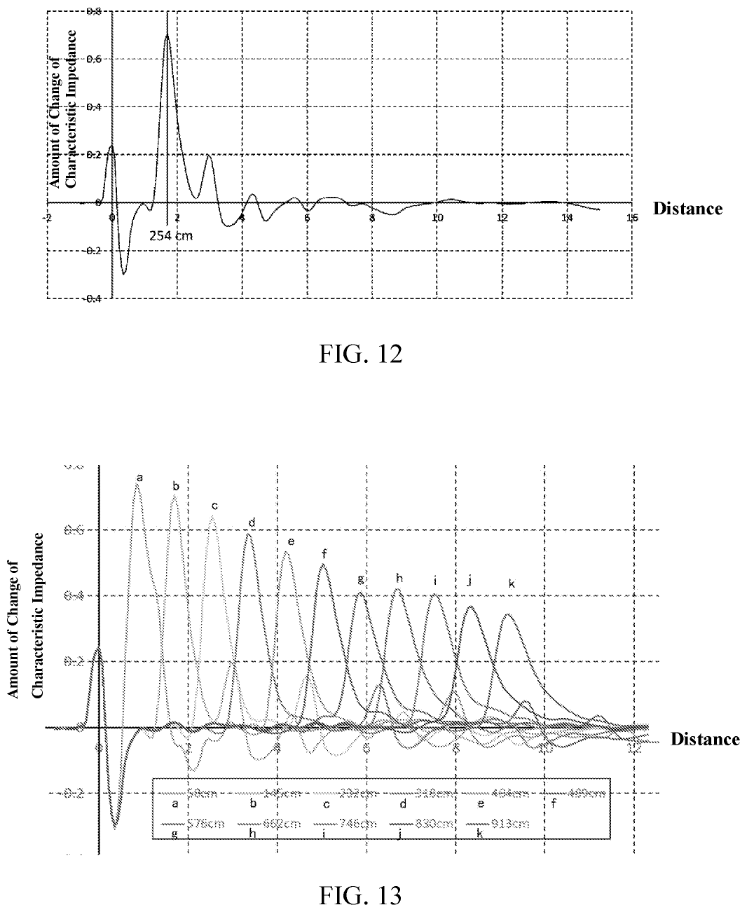

FIG. 12 shows, as an example, the measurement result of the characteristic impedance for a case where the simulated external damage is formed at a position of 232 cm from the base end of the specimen electric wire. In FIG. 12 and FIGS. 13 to 14C shown later, the time axis is converted to a distance from the base end on the horizontal axis and the characteristic impedance on the vertical axis. However, the numerical value provided to the horizontal axis does not indicate the absolute value of the distance, and is an amount proportional to the distance. The characteristic impedance on the vertical axis is indicated by an amount of change with a value at zero distance set to zero.

By seeing the measurement result in FIG. 12, large change originating from a device connection unit is seen in the vicinity of the zero distance, and in addition, a clear peak structure which discontinuously rises from the surrounding area is seen at a position corresponding to a 254-cm distance. This peak structure can be correlated to the change in the characteristic impedance due to the external damage. The position of the peak top is at the 254-cm distance, but falls within the error range of approximately 20 cm from the position at the 232-cm distance where the external damage is actually formed. From this result, by measuring the characteristic impedance between the conductive tape and the conductor constituting the core wire, it is confirmed that the formation of the external damage can be detected and further, the position of the external damage can be identified with high accuracy.

Further, FIG. 13 shows together a plurality of measurement results when the position to form the simulated external damage is changed. The external damage is formed at each of the positions described in the explanatory note corresponding to the signs in the graph (at the distances from the base end). From FIG. 13, as the forming position of the external damage is farther from the base end and from a to k, the positions of the peak tops of the characteristic impedances are shifted to the long-distance side. Any of the distance values of these peak tops coincides with the position where the external damage is actually formed, within the error range of approximately 20 cm. From this, by using the measurement of the characteristic impedance, it is confirmed that the formation of the damage can be detected to the position which is approximately 10 m ahead, and further, the damaged position can be identified at a resolution of approximately 20 cm. However, as the forming position of the external damage is farther from the base end and from the a to the k, the peak height becomes smaller, and the peak width becomes larger. That is, as the forming position of the external damage is farther from the base end, the detection sensitivity and the resolution in the position identification tend to be lower.

### [1-2] External Damage Detection in Electric Wire Having Branches

Next, in an electric wire having branches, it was confirmed whether the detection of external damage using the measurement of characteristic impedance could be performed.

### (Preparation of Specimen)

As a core wire, an electric wire having branch structures as shown in FIG. 9 was prepared. Here, branch wires 15A to 15C are branched from three branched portions 13A to 13C provided in the middle portion of a main wire 14, respectively. Conductive tapes were wound in a rough spiral in the respective portions of the main wire 14 and the branch wires 15A to 15C of the core wire 10′ to make a specimen electric wire. The conductive tapes respectively wound around the main wire 14 and the branch wires 15A to 15C were electrically contacted with each other. The type of the used conducive tape, the pitch of the spiral, and the ratio of the width of the conductive tape to the width of each of gaps were the same as the above test [1-1]. Simulated external damages which broke the conductive tapes were formed at predetermined positions of the main wire and the respective branch wires of this specimen electric wire.

### (Detection of External Damage)

Similarly to the above test [1-1], the measurement of characteristic impedance by the MCTDR method was performed.

### (Results)

FIG. 14A shows a measurement result for a case where no external damage is formed. On the other hand, FIG. 14B shows a measurement result when the external damage is formed in the branch wire 15A extending from the branched portion 13A which is the closest to the base end. The distance from the base end 1A to the externally damaged position was 4.0 m across the branched portion 13A.

When the state in FIG. 14A where there is no external damage and the case in FIG. 14B where the external damage is formed are compared, the measurement results of patterns which are very similar between both are obtained. An upward peak which does not exist in FIG. 14A is seen in the vicinity of the externally damaged position indicated by the star mark in FIG. 14B, and this peak can be correlated to the change in the characteristic impedance due to the formation of the external damage. However, in addition to this peak, many upward and downward peak structures which are the same as or larger than this peak appear, and it is difficult to clearly recognize the peak corresponding to the formation of the external damage from other peak structures and identify the formation of the external damage.

FIG. 14C shows a subtraction between the measurement results in FIGS. 14A and 14B. This subtraction is obtained by subtracting the characteristic impedance value before the external damage formation in FIG. 14A from the characteristic impedance value after the external damage formation in FIG. 14B. According to the subtraction display in FIG. 14C, the peak structure which is noticeable in the area on the short distance side in the measurement results in FIGS. 14A and 14B disappears. On the other hand, the upward peak clearly remains at the forming position of the external damage indicated by the star mark.

In this way, by taking the subtraction before and after the external damage formation with respect to the measurement results of the characteristic impedances, the change in the characteristic impedance originating from the external damage formation can be clearly recognized, and can be correlated to the external damage. Although the illustration of the result is omitted, also for a case where the external damage is formed in the branch wire 15B extending out from the second branched portion 13B from the base end, the external damage could be detected based on the change in the characteristic impedance by using a subtraction as above. From these results, even if the branch exists in the core wire, the external damage can be detected by measuring the characteristic impedance between the conductor constituting the core wire and the conductive tape, and in particular, by using the subtraction between the state where the external damage is formed and the state where the external damage is not formed, it is confirmed that the external damage can be detected with high sensitivity. Note that since the distance from the base end is too large beyond the third branched portion 13C from the base end, it was difficult to clearly detect the change in the characteristic impedance corresponding to the external damage even if the external damage was provided on any of the main wire side and the branch wire side.

[2] For Electric Wire Wound with Laminated Tape

Finally, also for an electric wire wound with a laminated tape, it was confirmed whether the detection of damage could be performed.

### (Preparation of Specimen)

As a laminated tape, an insulating nonwoven cloth was cut into a tape shape, and was sandwiched between copper tapes having a thickness of 0.1 mm and a width of 8 mm. The nonwoven cloth tape and each of the copper tapes were bonded by an adhesive layer. This laminated tape was wound in a spiral manner around an outer circumference of a resin hose (an outside diameter of 10 mm; a length of 7 m) which simulates the wire harness. The laminated tape was fixed to the resin hose by an adhesive tape. For the winding, the pitch of the spiral was approximately 25 mm. The ratio of the width of the laminated tape to the width of each of gaps not occupied by the laminated tape was approximately 1:1.

In the above specimen, two types of simulated external damages were formed. As the first type external damage, of the two-layered copper tapes constituting the laminated tape, the layer of the copper tape on the outside was broken at one position. The forming position of the breakage was 4.5 m from the base end of the specimen. As the second type external damage, one metal pin was penetrated through the laminated tape to cause the two-layered copper tapes to be electrically short-circuited. The forming position of the short circuit was 5 m from the base end of the specimen.

### (Detection of External Damage)

At the base end of the specimen prepared above, a reflection coefficient ρ was measured between the two-layered copper tapes constituting the laminated tape. The measurement was performed by the MCTDR method. During the measurement, the potential of the two-layered copper tapes was kept in the floating state. Note that when characteristic impedance between the two-layered copper tapes is Z₀ at a position where there is no damage and is Z_{L} at a position where the damage occurs, the reflection coefficient ρ is expressed by the following equation (1).

ρ=(Z_{L}−Z₀)/(Z_{L}+Z₀) (1)

That is, when the characteristic impedance increases at the damage position, the reflection coefficient also increases, and when the characteristic impedance decreases at the damage position, the reflection coefficient also decreases. Therefore, in this test, the reflection coefficient is measured as a characteristic in place of the characteristic impedance.

### (Results)

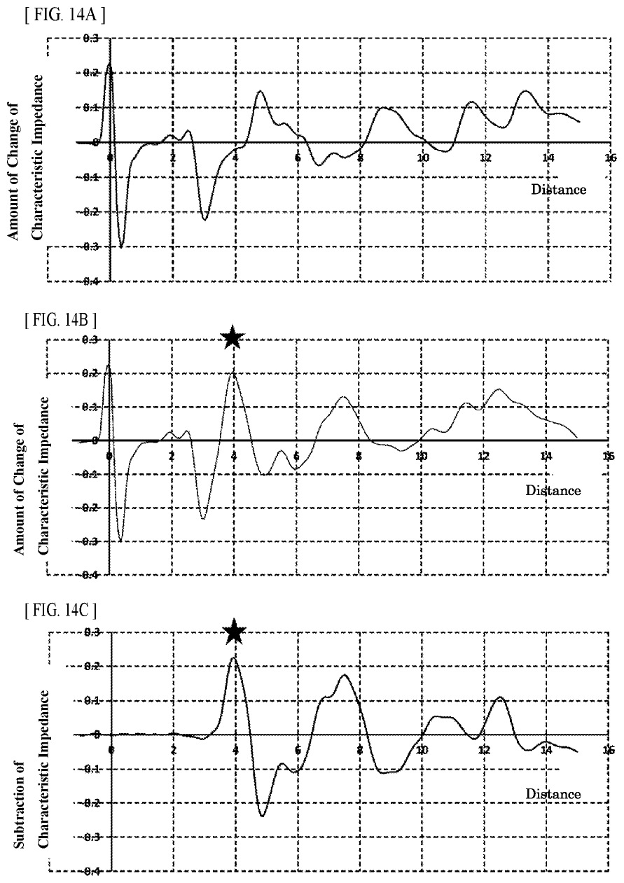

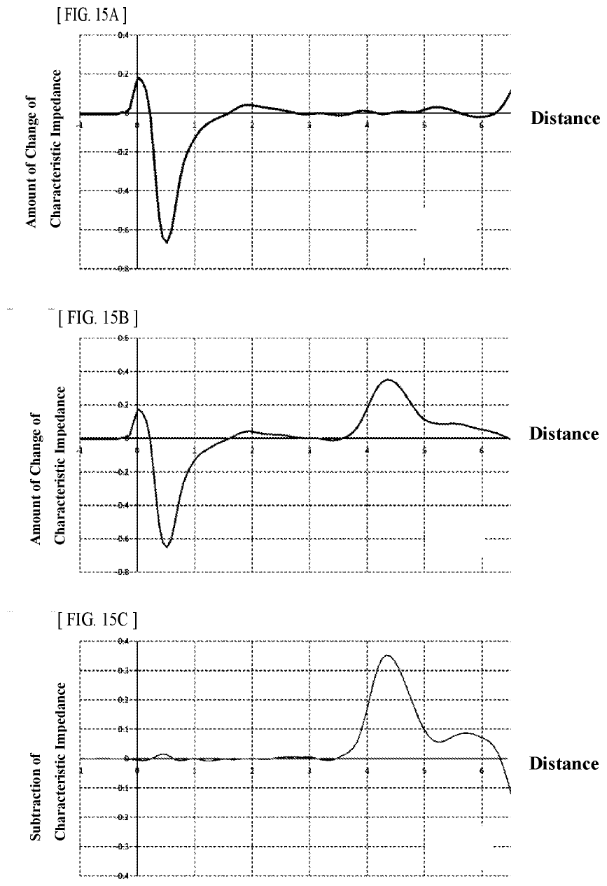

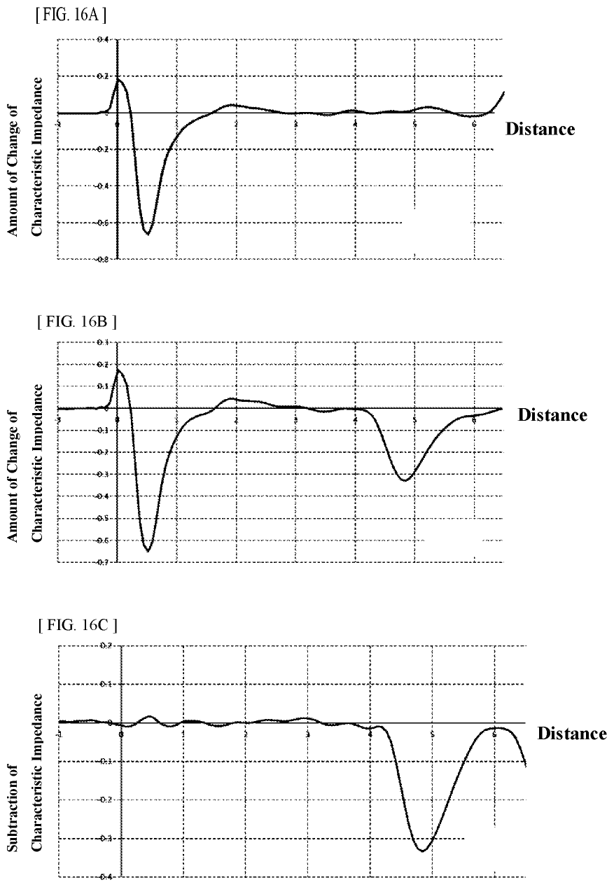

First, a result when breakage is formed in the copper tape as the external damage is confirmed. FIG. 15A shows a measurement result of the reflection coefficient in the normal state before the breakage formation, and FIG. 15B shows a measurement result of the reflection coefficient for a state after the breakage formation. Note that in FIGS. 15A to 16C, the time axis is converted to a distance from the base end (unit: m) on the horizontal axis and the reflection coefficient ρ on the vertical axis. By seeing the measurement result after the breakage formation in FIG. 15B, large change originating from the device connection unit is seen in the vicinity of zero distance, and in addition, a peak in the positive direction which is not seen in the measurement result in the normal state in FIG. 15A occurs in the vicinity of a 4.5-m distance. FIG. 15C shows a subtraction obtained by subtracting the reflection coefficient value before the breakage formation from the reflection coefficient value after the breakage formation, and in the subtraction, the peak structure in the positive direction becomes clearer.

Next, a result when a short circuit is formed in the copper tape as the external damage is confirmed. FIG. 16A shows a measurement result of the reflection coefficient in the normal state before the short circuit formation, and FIG. 16B shows a measurement result of the reflection coefficient for a state after the short circuit formation. In the measurement result after the short circuit formation in FIG. 16B, a peak in the negative direction which is not seen in the measurement result in the normal state in FIG. 16A occurs in the vicinity of a 5-m distance. FIG. 16C shows a subtraction obtained by subtracting the reflection coefficient value before the short circuit formation from the reflection coefficient value after the short circuit formation, and in the subtraction, the peak structure in the negative direction becomes clearer.

In this way, in the specimen around which the laminated tape is wound, also when the breakage is formed in the copper tape as the external damage, and also when the short circuit is formed as the external damage, these damages can be detected by performing the measurement of the reflection coefficient for comparison with the measurement result in the normal state. The damage position can also be identified. Further, it is shown that the case where the breakage is formed as the damage and the case where the short circuit is formed as the damage are opposite in the direction of the change in the reflection coefficient, and the type of the damage can be estimated from the direction of the change. When the breakage occurs in the copper tape, Z_{L} diverges infinitely in the equation (1), and a behavior in which the reflection coefficient ρ increases can be described. On the other hand, when the short circuit occurs in the copper tape, Z_{L} becomes zero in the equation (1), and a behavior in which the reflection coefficient ρ decreases can be described.

The embodiments of the present disclosure have been described above in detail, but the present invention is not limited to the above embodiments at all, and various modifications can be made within the scope not departing from the purport of the present invention. Also, the electric wire wound with the conductive tape and the electric wire wound with the laminated tape described above are applicable besides the case where they are to be inspected by the wire inspection system and the wire inspection method according to the embodiments of the present disclosure, and can achieve the object of performing the damage detection and the position identification by a simple structure.

### LIST OF REFERENCE SIGNS

1 Electric wire wound with conductive tape
1A Base end of electric wire
10, 10′ Core wire
11 Conductor
12 Insulation coating
13A-13C Branched portion
14 Main wire
15A-15C Branch wire
20 Conductive tape
25 Gap
3 Electric wire wound with laminated tape
30 Wire harness
31 Core wire
40 Laminated tape
41 Base material
42 Coating layer
43 Adhesive tape
9 Measurement device
100 Electric wire
120 Conductive layer
A Wire inspection system
A1 Memory unit
A2 Inspection unit
A3 Analysis unit
C Electric wire
Cp1-Cp6 Point on electric wire C
C1-C3 Electric wire
C2a Response signal of electric wire C2 at the time of inspection
C2b Response signal of electric wire C2 in initial state
D External damage
D1 Damage of conductive tape
P Peak
R Change area
S1-S4 Each step of wire inspection method

1. A wire inspection system for inspecting a damage state of an electric wire, wherein the electric wire including:
a core wire including a conductor and an insulation coating; and
a damage detection unit including at least one selected from a component of the core wire and a component other than the core wire which is arranged along the core wire,
wherein the damage detection unit gives a response signal which varies depending on the damage state of the electric wire when wire inspection is performed by inputting an electrical signal or an optical signal as an inspection signal,
the wire inspection system including:
a memory unit which stores the response signals obtained through the wire inspection at a first time point for a plurality of the electric wires constituting a wire group, identifying individual electric wires;
an inspection unit which performs the wire inspection on a subject electric wire selected from the wire group at a second time point later than the first time point, and
an analysis unit which compares, for the subject electric wire, the response signal at the first time point retrieved from the memory unit, with the response signal obtained by the inspection unit at the second time point, and, if a difference exists between the two response signals, judges that damage exists on the subject electric wire.

2. The wire inspection system according to claim 1, wherein the memory unit is provided at a portion apart from the inspection unit and the analysis unit.

3. The wire inspection system according to claim 1 or 2, wherein the analysis unit calculates a subtraction between the response signal at the first time point and the response signal at the second time point, and judges whether a difference exists between the two response signals based on the subtraction.

4. The wire inspection system according to claim 1, wherein the damage detection unit includes two conductive members electrically insulated from each other, wherein, in the wire inspection, characteristic impedance between the two conductive members is measured as the response signal using an electrical signal including an alternate-current component as the inspection signal, by a time domain reflectometry or a frequency domain reflectometry,
wherein the analysis unit correlates a domain where a difference exists between the response signals at the first and second time points with a position along an axial direction of the electric wire, and judges that damage exists at the position.

5. The wire inspection system according to claim 4, wherein the inspection signal includes a superimposition of signal components existing over a continuous frequency range and having mutually independent intensities, and has exclusion frequencies occupying a part of the frequency range, at which the components have no intensities or discontinuously smaller intensities than the components at adjacent frequencies; wherein
in the wire inspection, the characteristic impedance between the two conductive members is measured as the response signal by time domain reflectometry.

6. The wire inspection system according to claim 5, wherein, in the inspection signal, the exclusion frequencies include a frequency of an electromagnetic wave derived from a generation source external to the subject electric wire and propagating around the subject electric wire.

7. The wire inspection system according to claim 1, wherein the wire group includes a plurality of the electric wires of a same type.

8. The wire inspection system according to claim 1, wherein the electric wire included in the wire group has a branched portion in the middle thereof.

9. The wire inspection system according to claim 1, wherein the electric wire to be inspected includes a conductive tape wound around an outer circumference of the core wire in a spiral manner, having gaps between turns of the conductive tape that are not occupied by the conductive tape,
wherein the damage detection unit is composed of the conductor of the core wire and the conductive tape,
wherein, in the wire inspection, the characteristic impedance between the conductor and the conductive tape is measured as the response signal using the electrical signal including an alternate-current component as the inspection signal.

10. The wire inspection system according to claim 9, wherein the core wire has a single wire structure including only one insulated wire with the insulation coating on an outer circumference of the conductor.

11. The wire inspection system according to claim 1, wherein the electric wire to be inspected includes a laminated tape arranged around the outer circumference of the core wire, wherein
the laminated tape includes:
a base material which is a tape-shaped insulator or semiconductor; and
conductive coating layers formed on both sides of the base material, and
the damage detection unit composed of the two coating layers in the laminated tape,
wherein, in the wire inspection, the characteristic impedance between the conductor and the conductive tape is measured as the response signal using the electrical signal including an alternate-current component as the inspection signal.

12. The wire inspection system according to claim 11, wherein the core wire is in the form of a wire harness with the plurality of the electric wires made into a bundle, and the laminated tape is wound in a spiral manner around an outer circumference of the wire harness as a whole.

13. The wire inspection system according to claim 11, wherein the base material changes electrical properties depending on external environments.

14. A wire inspection method using the wire inspection system according to claim 1, including:
an initial data obtaining process in which the response signal is obtained at the first time point through the wire inspection performed for a plurality of the electric wires constituting the wire group;
a data storage process which stores the response signals obtained through the initial data obtaining process in the memory unit, identifying the individual electric wires;
a measurement process which performs the wire inspection on the subject electric wire through the inspection unit at the second time point, and
the analysis process which compares, for the subject electric wire, the response signal obtained at the first time point retrieved from the memory unit, with the response signal obtained by the measurement process at the second time point, and if a difference exists between the two response signals, judges that damage exists on the subject electric wire.

15. An electric wire, including:
a core wire including a conductor and an insulation coating covering an outer circumference of the conductor and exposed on the surface, and
a conductive tape arranged around an outer circumference of the core wire, wherein
the conductive tape is wound around a surface of the insulation coating in a spiral manner along the axial direction of the core wire, having gaps between turns in the spiral of the conductive tape that are not occupied by the conductive tape.

16. An electric wire, including:
a core wire including a conductor and an insulation coating covering an outer circumference of the conductor and exposed on the surface;
a laminated tape arranged around an outer circumference of the core wire, wherein
the laminated tape includes a base material which is a tape-shaped insulator or a semiconductor, and conductive coating layers formed on both sides of the base material.
